(19) United States
(12) Patent Application Publication
(10) Pub. No.: US 2025/0301800 A1
(43) Pub. Date: Sep. 25, 2025

(54) SOLAR CELL MODULE

(71) Applicant: KYOCERA CORPORATION, Kyoto (JP)

(72) Inventors: Ryota TESHIMA, Yasu-shi, Shiga (JP); Yuta NISHIO, Omihachiman-shi, Shiga (JP)

(21) Appl. No.: 18/869,234

(22) PCT Filed: May 22, 2023
(86) PCT No.: PCT/JP2023/018912

§ 371 Date: Nov. 25, 2024

(30) Foreign Application Priority Data
May 27, 2022 (JP) 2022-086771

(51) Int. Cl. H10F 19/80

(52) U.S. Cl. CPC H10F 19/804

(57) ABSTRACT

A solar cell module includes a first protective layer, a plurality of solar cell elements, and a filler. The first protective layer is made of a light-transmissive resin and includes a first surface and a second surface opposite to the first surface. The plurality of solar cell elements faces the second surface and is arranged along the second surface. The filler is in contact with the second surface and covers the plurality of solar cell elements. The plurality of solar cell elements includes two solar cell elements arranged in a first direction. The first surface includes a first area above the plurality of solar cell elements and a second area different from the first area. The first surface includes one or more linear recesses in the second area.

### CROSS-REFERENCE TO RELATED APPLICATION

This application claims priority to Japanese Patent Application No. 2022-86771 filed on May 27, 2022, the entire disclosure of which is incorporated herein by reference.

### TECHNICAL FIELD

The present disclosure relates to a solar cell module.

### BACKGROUND OF INVENTION

A known solar cell module includes multiple solar cell elements between a front protective layer and a back protective layer (refer to, for example, Patent Literature 1). In this solar cell module, the multiple solar cell elements are arranged in a plane and electrically connected to one another. The multiple solar cell elements are covered by a filler containing ethylene-vinyl acetate copolymer (EVA) as a main component.

### CITATION LIST

### Patent Literature

Patent Literature 1: WO 2021/070743

### SUMMARY

One or more aspects of the present disclosure are directed to a solar cell module.

In one aspect, a solar cell module includes a first protective layer, a plurality of solar cell elements, and a filler. The first protective layer is made of a light-transmissive resin and includes a first surface and a second surface opposite to the first surface. The plurality of solar cell elements faces the second surface and is arranged along the second surface. The filler is in contact with the second surface and covers the plurality of solar cell elements. The plurality of solar cell elements includes two solar cell elements arranged in a first direction. The first surface includes a first area above the plurality of solar cell elements and a second area different from the first area. The first surface includes one or more linear recesses in the second area.

### BRIEF DESCRIPTION OF THE DRAWINGS

FIG. 1 is a plan view of a solar cell module according to a first embodiment, illustrating its example appearance when viewed in plan.

FIG. 2 is an example imaginary cross-sectional view of the solar cell module taken along line II-II in FIG. 1.

FIG. 3 is an example imaginary cross-sectional view of the solar cell module taken along line III-III in FIG. 1.

FIG. 4 is a plan view of a first element surface of a solar cell element, illustrating its example structure.

FIG. 5 is a plan view of a second element surface of the solar cell element, illustrating its example structure.

FIG. 6 is an example imaginary cross-sectional view of the solar cell element taken along line VI-VI in FIGS. 4 and 5.

FIG. 7 is a diagram of the solar cell module according to the first embodiment, illustrating an example bent state.

FIG. 8 is a diagram of the solar cell element during manufacture with a specific example method for manufacturing the solar cell element, illustrating an example state of its imaginary cross section.

FIG. 9 is a diagram of the solar cell element during manufacture with the specific example method for manufacturing the solar cell element, illustrating an example state of its imaginary cross section.

FIG. 10 is a diagram of the solar cell element during manufacture with the specific example method for manufacturing the solar cell element, illustrating an example state of its imaginary cross section.

FIG. 11 is a diagram of the solar cell element during manufacture with the specific example method for manufacturing the solar cell element, illustrating an example state of its imaginary cross section.

FIG. 12 is a diagram of the solar cell element during manufacture with the specific example method for manufacturing the solar cell element, illustrating an example state of its imaginary cross section.

FIG. 13 is a diagram of the solar cell module according to the first embodiment during manufacture with a specific example method for manufacturing the solar cell module, illustrating an example state of its imaginary cross section.

FIG. 14 is a diagram of the solar cell module according to the first embodiment during manufacture with the specific method for manufacturing the solar cell module, illustrating an example state of its imaginary cross section.

FIG. 15 is an example imaginary cross-sectional view of a solar cell module according to a second embodiment taken at a position corresponding to the cross-sectional view in FIG. 2.

FIG. 16 is an example imaginary cross-sectional view of the solar cell module according to the second embodiment taken at a position corresponding to the cross-sectional view in FIG. 3.

FIG. 17 is a diagram of the solar cell module according to the second embodiment during manufacture with a specific example method for manufacturing the solar cell module, illustrating an example state of its imaginary cross section.

FIG. 18 is a diagram of the solar cell module according to the second embodiment during manufacture with the specific example method for manufacturing the solar cell module, illustrating an example state of its imaginary cross section.

FIG. 19 is a plan view of a solar cell module according to a third embodiment, illustrating its example appearance when viewed in plan.

FIG. 20 is an example imaginary cross-sectional view of the solar cell module in FIG. 19 taken along line XX-XX.

FIG. 21 is an example imaginary cross-sectional view of the solar cell module in FIG. 19 taken along line XXI-XXI.

FIG. 22 is a diagram of the solar cell module according to the third embodiment, schematically illustrating example paths of rainwater flowing on a first protective layer.

FIG. 23 is a diagram of the solar cell module according to the third embodiment during manufacture with a specific example method for manufacturing the solar cell module, illustrating an example state of its imaginary cross section.

FIG. 24 is a diagram of the solar cell module according to the third embodiment during manufacture with the specific example method for manufacturing the solar cell module, illustrating an example state of its imaginary cross section.

FIG. 25 is an example imaginary cross-sectional view of a solar cell module according to a fourth embodiment taken at a position corresponding to the cross-sectional view in FIG. 20.

FIG. 26 is an example imaginary cross-sectional view of the solar cell module according to the fourth embodiment taken at a position corresponding to the cross-sectional view in FIG. 21.

FIG. 27 is a diagram of the solar cell module according to the fourth embodiment during manufacture with a specific example method for manufacturing the solar cell module, illustrating an example state of its imaginary cross section.

FIG. 28 is a diagram of the solar cell module according to the fourth embodiment during manufacture with the specific example method for manufacturing the solar cell module, illustrating an example state of its imaginary cross section.

FIG. 29 is an example imaginary cross-sectional view of a solar cell module according to another embodiment taken at a position corresponding to the cross-sectional view in FIG. 21.

FIG. 30 is an example imaginary cross-sectional view of a solar cell module according to another embodiment taken at a position corresponding to the cross-sectional view in FIG. 21.

FIG. 31 is a diagram of a solar cell module according to another embodiment, schematically illustrating example paths of rainwater flowing on a first protective layer.

FIG. 32 is an example imaginary cross-sectional view of a solar cell module according to another embodiment taken at a position corresponding to the cross-sectional view in FIG. 2.

FIG. 33 is a plan view of a solar cell module according to another embodiment, illustrating an example appearance when viewed in plan.

FIG. 34 is a plan view of a solar cell module according to another embodiment, illustrating an example appearance when viewed in plan.

### DESCRIPTION OF EMBODIMENTS

A known solar cell module includes multiple solar cell elements between a front protective layer and a back protective layer. In this solar cell module, the multiple solar cell elements are arranged in a plane and electrically connected to one another. The multiple solar cell elements are covered by a filler containing ethylene-vinyl acetate copolymer (EVA) as a main component between the front protective layer and the back protective layer.

Solar cell modules are to be improved to be lighter and have higher power generation efficiency.

The inventors of the present disclosure thus have devised a technique for the solar cell module to be lighter and have higher power generation efficiency. First to fourth embodiments will now be described with reference to the drawings.

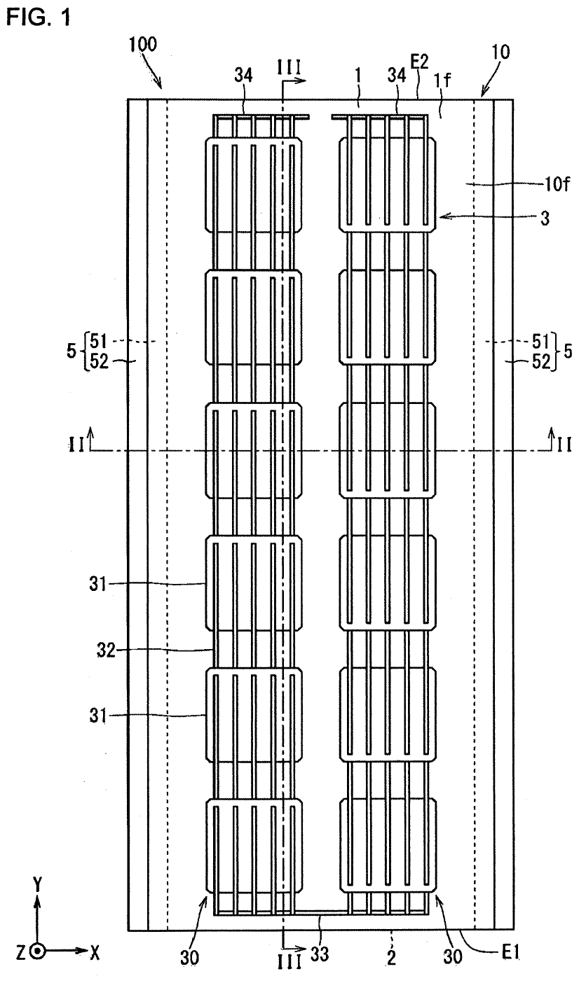

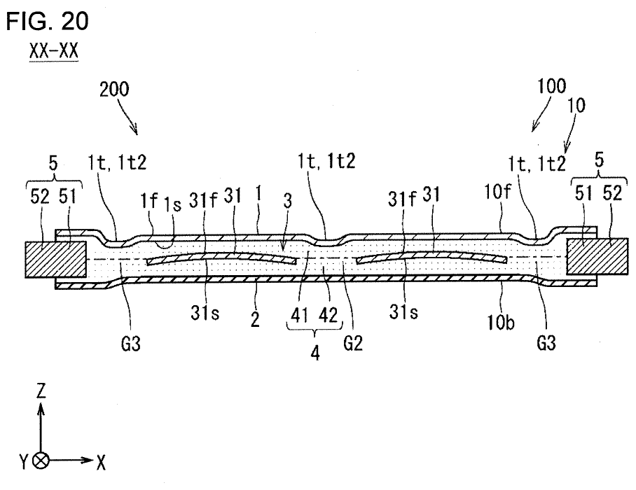

In the drawings, the same reference numerals denote the components with the same, substantially the same, or similar structures and functions. Thus, such components will not be described repeatedly. The drawings are schematic. FIGS. 1 to 34 illustrate a right-handed XYZ coordinate system. In this XYZ coordinate system, the longitudinal direction of a front surface 10f of a solar cell panel 10 is referred to as a negative Y-direction as a first direction. The lateral direction of the front surface 10f of the solar cell panel 10 is referred to as a positive X-direction as a second direction. The direction (also referred to as a normal direction) perpendicular to the front surface 10f orthogonal to both the negative Y-direction and the positive X-direction is referred to as a positive Z-direction. The direction opposite to the positive Z-direction is referred to as a negative Z-direction as a third direction. The direction opposite to the positive X-direction as the second direction is referred to as a negative X-direction as a fourth direction. The direction opposite to the negative Y-direction is referred to as a positive Y-direction as a fifth direction.

### 1. First Embodiment

### 1-1. Solar Cell Module

A solar cell module 100 according to a first embodiment will now be described with reference to FIGS. 1 to 7.

As illustrated in FIGS. 1 to 3, the solar cell module 100 includes, for example, a solar cell panel 10. The solar cell panel 10 includes, for example, a light receiving surface (also referred to as the front surface) 10f that mainly receives light, and a back surface 10b opposite to the front surface 10f. In the first embodiment, the front surface 10f faces in the positive Z-direction. The back surface 10b faces in the negative Z-direction. When the solar cell module 100 is used outdoors for power generation, for example, the positive Z-direction is set to, for example, the direction facing the sun at solar noon. In the example in FIG. 1, the front surface 10f is rectangular. The solar cell module 100 may further include a terminal box (not illustrated) for outputting power generated in the solar cell panel 10.

As illustrated in FIGS. 1 to 3, the solar cell panel 10 includes, for example, a first protective layer 1, a second protective layer 2, a solar cell 3, a filler 4, and supports 5.

### 1-1-1. First Protective Layer

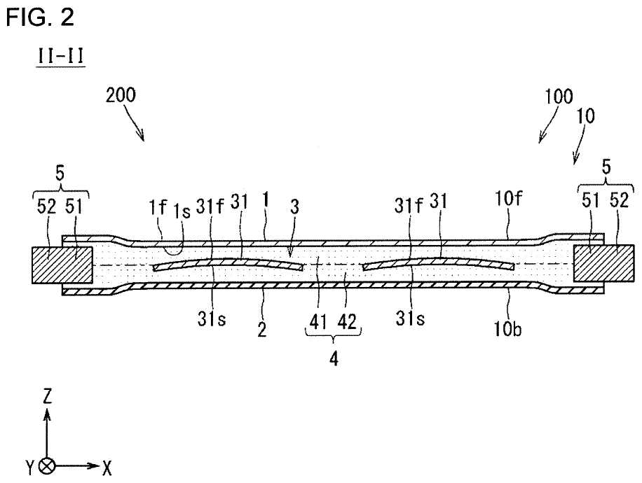

As illustrated in FIG. 2, the first protective layer 1 includes, for example, a first surface 1f and a second surface 1s. In the first embodiment, the first surface 1f serves as, for example, the front surface 10f of the solar cell panel 10. In other words, the first protective layer 1 is rectangular. In the example in FIGS. 1 to 3, the first surface 1f is exposed to a space (also referred to as an external space) 200 outside the solar cell module 100. The second surface 1s is a surface of the first protective layer 1 opposite to the first surface 1f.

The first protective layer 1 is, for example, light-transmissive. More specifically, the first protective layer 1 is, for example, transmissive to light in a specific wavelength range. The specific wavelength range includes, for example, the wavelength of light photoelectrically convertible with the solar cell 3. When the specific wavelength range includes the wavelength of sunlight with higher irradiation intensity, the solar cell module 100 can have higher photoelectric conversion efficiency.

The material for the first protective layer 1 is, for example, a light-transmissive resin. In other words, the first protective layer 1 is made of a light-transmissive resin. The light-transmissive resin may be weather-resistant. Being weather-resistant refers to, for example, being less likely to change, or more specifically, being less likely to deform, discolor, or deteriorate in outdoor use. The light-transmissive resin used as the material for the first protective layer 1 may be flexible. Being flexible refers to, for example, being soft and pliable. The first protective layer 1 may include, for example, a single resin layer.

With the resin used as the material, the first protective layer 1 is, for example, moisture-permeable and watertight. Being moisture-permeable and watertight refers to reducing water entry, such as water droplets, from the external space 200 outside the solar cell module 100 toward the solar cell 3, and also facilitating passage of moisture from the filler 4 toward the external space 200. The light-transmissive and weather-resistant resin includes, for example, a fluorine-based resin. The fluorine-based resin includes, for example, fluorinated ethylene propylene (FEP), ethylene tetrafluoroethylene (ETFE), and ethylene chlorotrifluoroethylene (ECTFE). The first protective layer 1 may include, for example, two or more resin layers. In this case, the fluorine-based resin used for the first protective layer 1 may be, for example, two or more different resins. Thus, the fluorine-based resin used for the first protective layer 1 may include, for example, one or more of FEP, ETFE, and ECTFE.

The first protective layer 1 has a thickness of, for example, about 0.05 to 0.5 millimeters (mm). The first protective layer 1 may be made of a moisture-permeable resin with relatively low density. The first protective layer 1 may be thin. In this case, the first protective layer 1 is light. Thus, the solar cell module 100 can be lighter and thinner than a structure including, for example, high-density glass with a thickness greater than or equal to about 1 mm in place of the first protective layer 1.

Note that the material for the first protective layer 1 may include a resin different from the fluorine-based resin instead of or in addition to the fluorine-based resin. The resin different from the fluorine-based resin is, for example, an acrylic resin or polycarbonate. In this case, the resin has a thickness of, for example, about 0.03 to 0.6 mm. The first protective layer 1 may include multiple different resin layers stacked on one another.

### 1-1-2. Solar Cell

The solar cell 3 is located between, for example, the first protective layer 1 and the second protective layer 2. In other words, the solar cell 3 faces the first protective layer 1 and the second protective layer 2 in the Z-direction.

As illustrated in FIGS. 1 to 3, the solar cell 3 includes, for example, multiple solar cell elements 31. The multiple solar cell elements 31 are located between the second surface 1s of the first protective layer 1 and the second protective layer 2. In other words, the multiple solar cell elements 31 face the second surface 1s of the first protective layer 1. The multiple solar cell elements 31 are arranged along the second surface 1s of the first protective layer 1. In other words, the multiple solar cell elements 31 are arranged along the second surface 1s of the first protective layer 1 in a plane. In the example in FIGS. 1 to 3, the multiple solar cell elements 31 are arranged two-dimensionally.

The solar cell 3 further includes, for example, multiple first wires 32, a second wire 33, and third wires 34.

The solar cell 3 includes, for example, multiple solar cell strings 30. In the example in FIGS. 1 to 3, the solar cell 3 includes two solar cell strings 30 as the multiple solar cell strings 30. The multiple solar cell strings 30 are, for example, arranged in the X-direction.

Each of the multiple solar cell strings 30 includes, for example, two or more solar cell elements 31 and multiple first wires 32.

In the first embodiment, each of the solar cell strings 30 includes the two or more solar cell elements 31 arranged in, for example, the negative Y-direction as the first direction. In the example in FIGS. 1 to 3, each of the solar cell strings 30 includes six solar cell elements 31 as the two or more solar cell elements 31. Note that each of the solar cell strings 30 may include two solar cell elements 31 or three or more solar cell elements 31 as the two or more solar cell elements 31. In other words, in the solar cell module 100, the multiple solar cell elements 31 include two solar cell elements 31 arranged in the negative Y-direction as the first direction.

The multiple first wires 32 electrically connect, for example, two solar cell elements 31 of the two or more solar cell elements 31 adjacent to each other. The second wire 33 electrically connects two solar cell strings 30 of the two or more solar cell strings 30 adjacent to each other. Each of the third wires 34 is connected to the corresponding one of the two solar cell strings 30. In the example in FIGS. 1 to 3, the solar cell 3 includes one of the third wires 34 connected to the corresponding one of the solar cell strings 30 located farthest in the negative X-direction and the other of the third wires 34 connected to the corresponding one of the solar cell strings 30 located farthest in the positive X-direction. Each of the two third wires 34 includes a portion extending outside the solar cell panel 10.

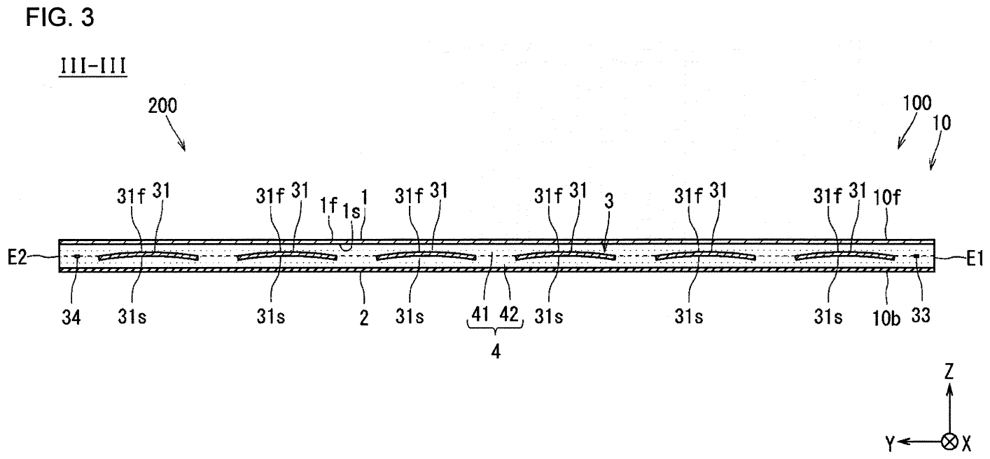

Each of the multiple solar cell elements 31 can convert light energy to electrical energy. Each of the multiple solar cell elements 31 is, for example, a plate. Each of the solar cell elements 31 includes a first element surface 31f and a second element surface 31s. The first element surface 31f faces the second surface 1s of the first protective layer 1. The second element surface 31s is a surface of the solar cell element 31 opposite to the first element surface 31f. In other words, the second element surface 31s faces the second protective layer 2. In the example in FIGS. 2 and 3, the first element surface 31f faces in the positive Z-direction. The second element surface 31s faces in the negative Z-direction. In this case, for example, the first element surface 31f mainly serves as a surface to receive light (also referred to as a light-receiving surface). The second element surface 31s mainly serves as a surface to receive no light (also referred to as a non-light receiving surface). Each of the first element surface 31f and the second element surface 31s is, for example, rectangular and may be substantially square. Each of the first element surface 31f and the second element surface 31s may have cut corners. Each of the first element surface 31f and the second element surface 31s is, for example, substantially square, with each side having a length of about 100 to 250 mm. Each of the first element surface 31f and the second element surface 31s may be, for example, substantially rectangular.

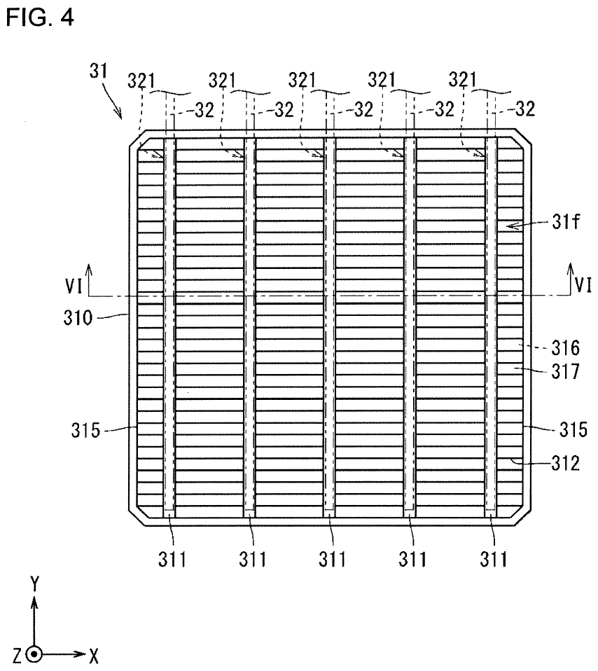

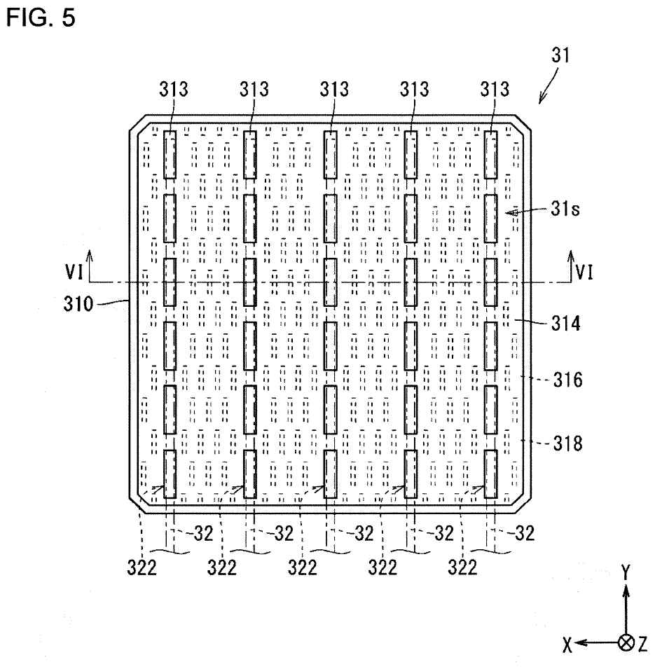

In the first embodiment, as illustrated in FIGS. 4 and 5, each of the multiple solar cell elements 31 includes a semiconductor substrate 310, first electrodes 311, second electrodes 312, third electrodes 313, and a fourth electrode 314.

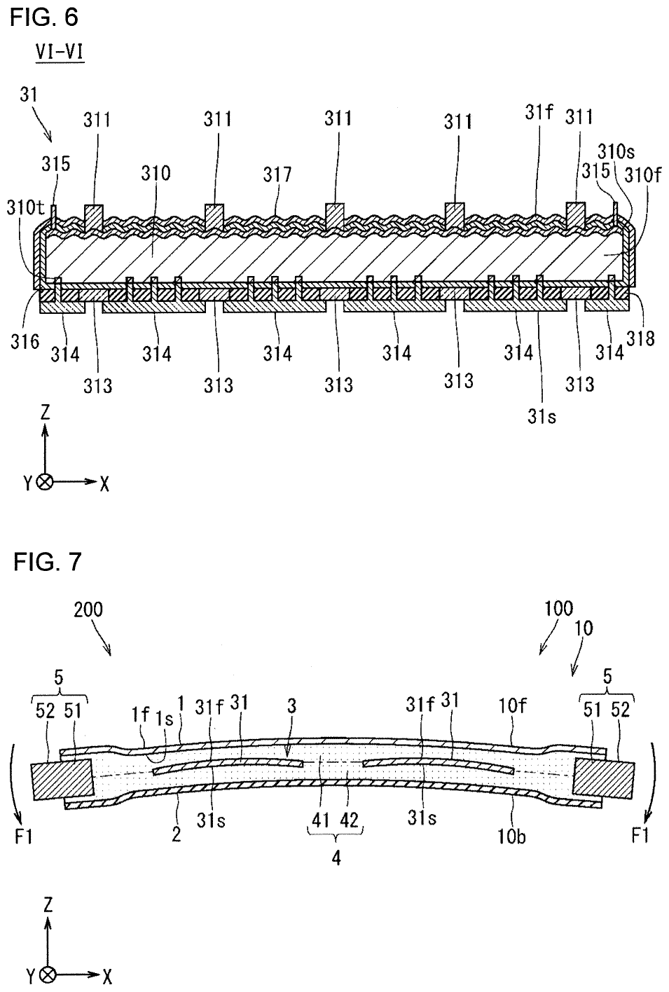

The semiconductor substrate 310 is, for example, a substrate of a crystalline semiconductor such as crystalline silicon, an amorphous semiconductor such as amorphous silicon, or a compound semiconductor such as a compound of four elements, copper, indium, gallium, and selenium, or a compound of two elements, cadmium and tellurium. In this example, the semiconductor substrate 310 is a substrate of crystalline silicon. In this case, as illustrated in FIG. 6, the semiconductor substrate 310 mainly includes a semiconductor area 310f (also referred to as a first conductivity type area) of a first conductivity type and includes a semiconductor area 310s (also referred to as a second conductivity type area) of a second conductivity type opposite to the first conductivity type. The first conductivity type area 310f is located in, for example, a portion of the semiconductor substrate 310 adjacent to the second element surface 31s in the negative Z-direction. The second conductivity type area 310s is located in, for example, a surface layer of the semiconductor substrate 310 adjacent to the first element surface 31f in the positive Z-direction. When, for example, the first conductivity type is p-type, the second conductivity type is n-type. When, for example, the first conductivity type is n-type, the second conductivity type is p-type. The semiconductor substrate 310 thus has a p-n junction at the interface between the first conductivity type area 310f and the second conductivity type area 310s. The semiconductor substrate 310 has a thickness of, for example, about 0.15 to 0.5 mm.

The first electrodes 311 and the second electrodes 312 are located in, for example, a surface portion of the semiconductor substrate 310 adjacent to the first element surface 31f. The first electrodes 311 are, for example, busbar electrodes. The second electrodes 312 are, for example, finger electrodes. In the first embodiment, each of the solar cell elements 31 includes the multiple first electrodes 311 and the multiple second electrodes 312. In the example in FIG. 4, the multiple first electrodes 311 that are substantially parallel to one another and the multiple second electrodes 312 that are substantially parallel to one another are located on a portion of the semiconductor substrate 310 adjacent to the first element surface 31f. More specifically, five first electrodes 311 as the multiple first electrodes 311 substantially parallel to one another and many second electrodes 312 as the multiple second electrodes 312 substantially parallel to one another are located substantially orthogonal to one another. In the example in FIG. 4, each of the multiple first electrodes 311 is elongated in the negative Y-direction as the first direction. Each of the multiple second electrodes 312 is linear in the positive X-direction as the second direction. As illustrated in FIG. 4, each of the solar cell elements 31 may include, for example, fifth electrodes 315 located along an outer edge in the negative X-direction and the fifth electrodes 315 located along an outer edge in the positive X-direction on a portion adjacent to the first element surface 31f. Each of the fifth electrodes 315 connects, for example, the many substantially parallel second electrodes 312 to one another.

An anti-reflection film 317 may be located on portions without the first electrodes 311 or the second electrodes 312 on the second conductivity type area 310s in the semiconductor substrate 310. The anti-reflection film 317 is, for example, an insulating film of silicon nitride. For example, as illustrated in FIGS. 4 and 6, a passivation film 316 may be located between the second conductivity type area 310s in the semiconductor substrate 310 and the anti-reflection film 317. The passivation film 316 is, for example, a thin film of an oxide, such as aluminum oxide, or a nitride.

When containing, for example, silver as their main component, the first electrodes 311 may be formed by applying a silver paste in an intended shape with a method such as screen printing and then firing the silver paste. The main component refers to the component with a ratio (also referred to as a content) that is the greatest (highest) of all the contained constituents. The silver paste is, for example, a metal paste containing metal powder that contains silver as a main component, an organic vehicle, and a glass frit. When containing, for example, silver as their main component, the second electrodes 312 may be formed by applying a silver paste in an intended shape with a method such as screen printing and then firing the silver paste. When containing, for example, silver as their main component, the fifth electrodes 315 may be formed by applying a silver paste in an intended shape with a method such as screen printing and then firing the silver paste. The first electrodes 311, the second electrodes 312, and the fifth electrodes 315 may be formed, for example, in separate processes or in the same process.

The third electrodes 313 and the fourth electrode 314 are located on, for example, portions of the semiconductor substrate 310 adjacent to the second element surface 31s. The third electrodes 313 are, for example, busbar electrodes. In the example in FIG. 5, the multiple third electrodes 313 that are substantially parallel to one another are located on portions of the semiconductor substrate 310 adjacent to the second element surface 31s. More specifically, five rows of third electrodes 313 substantially parallel to one another are located on the portions of the semiconductor substrate 310 adjacent to the second element surface 31s. Each of the five rows of third electrodes 313 extends in the negative Y-direction as the first direction. More specifically, each of the five rows of third electrodes 313 includes, for example, multiple electrode portions arranged in a row. The multiple electrode portions are, for example, six electrode portions. The fourth electrode 314 is located on substantially the entire surface of the semiconductor substrate 310 adjacent to the second element surface 31s on which no third electrodes 313 are located, except portions on which the third electrodes 313 and the fourth electrode 314 overlap and are connected to each other. Note that the fourth electrode 314 may not be located on substantially the entire surface and may be, for example, arranged in a grid.

For example, as illustrated in FIGS. 5 and 6, the passivation film 316 may be located between the first conductivity type area 310f in the semiconductor substrate 310 and the third electrodes 313, and between the first conductivity type area 310f and the fourth electrode 314. The passivation film 316 is, for example, a thin film of an oxide, such as aluminum oxide, or a nitride. In this case, the passivation film 316 has an intended pattern between the first conductivity type area 310f and the third electrodes 313 and between the first conductivity type area 310f and the fourth electrode 314. A film (also referred to as a protective film) 318 for protecting the passivation film 316 may also be located between the passivation film 316 and the fourth electrode 314. The protective film 318 is, for example, a thin film of an oxide such as silicon oxide. The protective film 318 has an intended pattern between the passivation film 316 and the fourth electrode 314. As illustrated in FIG. 6, for example, the protective film 318 may not be located between the passivation film 316 and the third electrodes 313. In this case, the protective film 318 includes multiple holes in portions at which the third electrodes 313 are located. For example, the protective film 318 may be located between the passivation film 316 and the third electrodes 313. Each of the passivation film 316 and the protective film 318 includes, for example, multiple through-holes to allow portions of the fourth electrode 314 to come in contact with the first conductivity type area 310f. The first conductivity type area 310f includes, in surface portions in contact with the fourth electrode 314, areas (also referred to as high-concentration areas, or as back surface fields or BSFs) 310t with a higher density of a dopant element of the first conductivity type than the other areas in the first conductivity type area 310f.

When containing, for example, silver as their main component, the third electrodes 313 may be formed by applying a silver paste in an intended shape with a method such as screen printing and then firing the silver paste. When containing, for example, aluminum as its main component, the fourth electrode 314 may be formed by applying an aluminum paste in an intended shape with a method such as screen printing and then firing the aluminum paste. The aluminum paste is, for example, a metal paste containing a metal powder that contains aluminum as a main component, an organic vehicle, and a glass frit.

The first wires 32 electrically connect, for example, the first electrodes 311 in one of the solar cell elements 31 to the third electrodes 313 in another of the solar cell elements 31 adjacent to the solar cell element 31. In the example in FIGS. 4 and 5, imaginary thin two-dot-dash lines indicate the outer edges of the multiple first wires 32 attached to each of the solar cell elements 31. In the example in FIGS. 1 to 5, the first wires 32 are elongated in the negative Y-direction as the first direction. The first wires 32 are, for example, bonded to the first electrodes 311 and the third electrodes 313. More specifically, for example, joints (also referred to as first joints) 321 are located between the first wires 32 and the respective first electrodes 311. The first joints 321 join the first wires 32 and the respective first electrodes 311. Thus, the first wires 32 are, for example, bonded to the first electrodes 311 in one of the solar cell elements 31 with the first joints 321 between the first wires 32 and the first electrodes 311. For example, joints (also referred to as second joints) 322 are located between the first wires 32 and the respective third electrodes 313. The second joints 322 join the first wires 32 and the respective third electrode 313. Thus, the first wires 32 are, for example, bonded to the third electrodes 313 in another of the solar cell elements 31 adjacent to the solar cell element 31 with the second joints 322 between the first wires 32 and the third electrodes 313.

The first wires 32 are, for example, linear or strip-shaped conductive metal members. The material for the first joints 321 and the second joints 322 is, for example, an alloy with a low melting point such as solder, or a single metal with a low melting point. More specifically, for example, each of the first wires 32 is copper foil with a thickness of about 0.1 to 0.2 mm and a width of about 1 to 2 mm. In this case, the first wires 32 may have their entire surfaces covered with solder. The first wires 32 are, for example, electrically connected to the first electrodes 311 and the third electrodes 313 by soldering. For example, solder portions between the first wires 32 and the first electrodes 311 are the first joints 321. For example, solder portions between the first wires 32 and the third electrodes 313 are the second joint 322.

### 1-1-3. Filler

The filler 4 is in contact with the second surface 1s. The filler 4 covers the multiple solar cell elements 31. In the first embodiment, the filler 4 covers the multiple solar cell elements 31 between the first protective layer 1 and the second protective layer 2. In other words, the filler 4 covers the solar cell 3 in a space (also referred to as a gap space) between the first protective layer 1 and the second protective layer 2, and fills the gap space. In still other words, the filler 4 includes a surface adjacent to the first protective layer 1 and in contact with the second surface Is of the first protective layer 1, and a surface adjacent to the second protective layer 2 and in contact with the second protective layer 2.

The filler 4 includes, for example, a filler (also referred to as a first filler) 41 adjacent to the front surface 10f and a filler (also referred to as a second filler) 42 adjacent to the back surface 10b. The first filler 41 covers, for example, the entire surface of the solar cell 3 adjacent to the first protective layer 1. In other words, the first filler 41 covers, for example, the multiple solar cell elements 31 between the first protective layer 1 and the multiple solar cell elements 31. The second filler 42 covers, for example, the entire surface of the solar cell 3 adjacent to the second protective layer 2. In other words, the second filler 42 covers, for example, the multiple solar cell elements 31 between the second protective layer 2 and the multiple solar cell elements 31. Thus, in the first embodiment, the solar cell 3 is, for example, sandwiched and covered by the first filler 41 and the second filler 42. The filler 4 can thus, for example, maintain the orientation of the solar cell 3.

The filler 4 is, for example, light-transmissive. The filler 4 is, for example, transmissive to light in the specific wavelength range described above. For example, with at least the first filler 41 of the first filler 41 and the second filler 42 in the filler 4 being light-transmissive, incident light through the front surface 10f can reach the solar cell 3.

The material for the first filler 41 is, for example, EVA, a polyvinyl acetal such as polyvinyl butyral (PVB), or an acid-modified resin. For example, with the material for the first filler 41 being EVA, which is relatively inexpensive, the first filler 41 can easily protect the multiple solar cell elements 31. The acid-modified resin is, for example, a modified polyolefin resin formed by graphitically modifying a polyolefin resin with an acid. The acid usable for graphitically modifying an acid-modified resin is, for example, an acrylic acid, a methacrylic acid, a maleic acid, a fumaric acid, an itaconic acid, maleic anhydride, hemic anhydride, itaconic anhydride, or citraconic anhydride. The material for the second filler 42 is, for example, EVA, a polyvinyl acetal such as PVB, or an acid-modified resin, as for the first filler 41. Each of the first filler 41 and the second filler 42 may contain, for example, two or more materials.

The second filler 42 may contain, for example, a pigment. When containing, for example, a white pigment, the second filler 42 can reflect light passing through the solar cell 3, causing the light to enter the solar cell 3 again. This can improve the power generation efficiency of the solar cell module 100.

Note that the filler 4 may include the first filler 41 without including the second filler 42. In this case, the first filler 41 covers the solar cell 3 between the first protective layer 1 and the second protective layer 2. In other words, the first filler 41 covers the multiple solar cell elements 31 between the first protective layer 1 and the second protective layer 2.

As illustrated in FIG. 2, for example, the filler 4 may have a smaller thickness at a portion covering the solar cell 3, and may have a greater thickness at portions between the solar cell 3 and the supports 5. In this case, for example, the maximum thickness of the filler 4 at the portions between the solar cell 3 and the supports 5 is greater than the maximum thickness of the filler 4 at a portion between two adjacent solar cell elements 31 of the multiple solar cell elements 31. In other words, the distance between the first protective layer 1 and the second protective layer 2 may be smaller at a portion sandwiching the solar cell 3 and larger at portions sandwiching spaces between the solar cell 3 and the supports 5. In still other words, the maximum distance between the first protective layer 1 and the second protective layer 2 may be greater at the portions sandwiching the spaces between the solar cell 3 and the supports 5 than at the portion sandwiching the solar cell 3. As illustrated in FIG. 2, for example, the filler 4 may also include, in at least parts of the spaces between the supports 5 and the solar cell 3, portions at which the thickness gradually increases from the solar cell 3 toward the respective supports 5. In other words, for example, the filler 4 may include, in at least parts of the spaces between the supports 5 and the solar cell 3, portions at which the thickness of the filler 4 monotonically increases from the solar cell 3 toward the respective supports 5.

Note that, in the example in FIG. 2, the filler 4 is line symmetric with respect to an XY plane. However, the drawing is schematic, and the structure is not limited to this example.

### 1-1-4. Second Protective Layer

The second protective layer 2 serves as, for example, the back surface 10b of the solar cell panel 10. The second protective layer 2 is, for example, in contact with a surface of the filler 4 away from the first protective layer 1. In other words, the second protective layer 2 is in contact with the filler 4 at a position away from the first protective layer 1. In still other words, the second protective layer 2 is in contact with the filler 4 on the surface of the filler 4 away from the surface in contact with the first protective layer 1. In the first embodiment, the second protective layer 2 faces the solar cell 3 and a first portion 51 of each of the supports 5 in the Z-direction. The first portion 51 is a portion of each of the supports 5 located closer to the solar cell 3 than to a second portion 52 of the support 5 in the X-direction.

The second protective layer 2 can protect, for example, the solar cell 3 on the back surface 10b. The second protective layer 2 is, for example, a back sheet serving as the back surface 10b. The back sheet has a thickness of, for example, about 0.15 to 0.5 mm. The material for the back sheet is, for example, a resin. The resin may be, for example, the same material as the first protective layer 1. The second protective layer 2 has the same or substantially the same shape as the first protective layer 1 when viewed in plan from the back surface 10b. For example, each of the first protective layer 1 and the second protective layer 2 has a rectangular profile when viewed in plan from the back surface 10b.

### 1-1-5. Support

The supports 5 increase the rigidity of the solar cell panel 10. For example, the supports 5 have higher rigidity than the rigidity of the first protective layer 1, the second protective layer 2, or the filler 4. In other words, the supports 5 are, for example, rigid members as objects with high rigidity. The material for the supports 5 is, for example, a metal. The metal is, for example, aluminum or stainless steel.

The supports 5 are spaced from and adjacent to the solar cell 3. More specifically, the supports 5 are spaced from and adjacent to the solar cell 3 when viewed in plan. Each of the supports 5 includes the first portion 51 and the second portion 52. Unless otherwise specified, being viewed in plan refers to a plan view in which each component is viewed in the negative Z-direction as the third direction. In other words, the supports 5 are spaced from and adjacent to the solar cell 3 in the positive X-direction as the second direction when viewed in plan toward the first surface If of the first protective layer 1.

The first portion 51 of each of the supports 5 is covered by the filler 4 between the first protective layer 1 and the second protective layer 2. In other words, the first portion 51 faces the second surface 1s of the first protective layer 1. The first portion 51 also faces the second protective layer 2. In the example in FIG. 2, the first portion 51 faces the second surface 1s of the first protective layer 1 in the Z-direction. The first portion 51 also faces the second protective layer 2 in the Z-direction. In other words, the filler 4 includes portions each located between the second surface 1s of the first protective layer 1 and the corresponding first portion 51. More specifically, the first filler 41 includes portions each located between the second surface 1s of the first protective layer 1 and the corresponding first portion 51 in the negative Z-direction as the third direction. The filler 4 also includes portions each located between the second protective layer 2 and the corresponding first portion 51. More specifically, the second filler 42 includes portions each located between the corresponding first portion 51 and the second protective layer 2 in the negative Z-direction as the third direction.

The second portion 52 of each of the supports 5 is located away from the solar cell 3. In other words, each of the supports 5 includes the first portion 51 adjacent to the solar cell 3 and the second portion 52 away from the solar cell 3 with respect to the first portion 51. The second portion 52 may be a portion of each of the supports 5 other than the first portion 51. In still other words, the second portion 52 extends from an end of the corresponding first portion 51 and protrudes from the filler 4 covering the first portion 51 away from the solar cell 3. More specifically, the second portion 52 is located away from the solar cell 3 (or located outside) with respect to the corresponding first portion 51 when viewed in plan. The second portion 52 does not face the second surface 1s of the first protective layer 1 or is not covered by the filler 4. In the example in FIGS. 1 and 2, the second portion 52 protrudes from the corresponding first portion 51 toward outside the first protective layer 1 and the second protective layer 2 when viewed in plan. In other words, the second portion 52 does not face the first protective layer 1 in the Z-direction. The second portion 52 does not face the second protective layer 2 in the Z-direction. In other words, the first portion 51 is located closer to the solar cell 3 (or located inside) with respect to the corresponding second portion 52 when viewed in plan.

In the example in FIGS. 1 and 2, each of the supports 5 is a plate. More specifically, the supports 5 are rectangular when viewed in plan. In the example in FIG. 2, the supports 5 have rectangular XZ cross sections. The supports 5 may have their corners chamfered as appropriate. The supports 5 have their longitudinal directions along, for example, one side of the first protective layer 1. In this example, the longitudinal directions of the supports 5 are aligned with the Y-direction. The supports 5 have their longitudinal directions in, for example, a direction (also referred to as an arrangement direction) in which the two or more solar cell elements 31 in one of the solar cell strings 30 are arranged. In this example, the arrangement direction of the multiple solar cell elements 31 in a single solar cell string 30 is aligned with the Y-direction. In other words, the supports 5 have their longitudinal directions in, for example, the longitudinal directions of the first wires 32. In this example, the longitudinal directions of the first wires 32 are aligned with the Y-direction.

In the first embodiment, the supports 5 in the solar cell panel 10 are two supports 5. The two supports 5 include a first support 5 and a second support 5. In the example in FIGS. 1 and 2, the first support 5 is located at an end of the solar cell panel 10 in the negative X-direction as the fourth direction. The second support 5 is located at an end of the solar cell panel 10 in the positive X-direction as the second direction. In the first support 5, the second portion 52 is adjacent to the first portion 51 in the negative X-direction as the fourth direction. In the second support 5, the second portion 52 is adjacent to the first portion 51 in the positive X-direction as the second direction.

The first support 5 is located along a first side of the first protective layer 1. The first side is at an end of the first protective layer 1 in the negative X-direction as the fourth direction. The second support 5 is located along a second side of the first protective layer 1. The second side is at an end of the first protective layer 1 in the positive X-direction as the second direction. In the example in FIGS. 1 and 2, each of the first side and the second side extends in the Y-direction. Each of the two supports 5 includes a rectangular front surface and a rectangular back surface with its longitudinal direction aligned with the Y-direction and its lateral direction aligned with the X-direction. Each of the supports 5 has, for example, the same or substantially the same length as the first protective layer 1. Each of the supports 5 has a length (also referred to as a width) of, for example, greater than or equal to several tens of millimeters in the lateral direction. In each of the supports 5, the first portion 51 has a length (width) of, for example, about 20 to 80% of the width of the support 5. The supports 5 are thus bonded to the filler 4 with relatively high bonding strength. Each of the supports 5 has a greater thickness than, for example, the solar cell 3. Each of the supports 5 has a thickness of, for example, about 1 to 5 mm.

The second portion 52 of each of the supports 5 is attached to, for example, a portion (also referred to as an attachment destination portion) of a building material. For example, the second portion 52 may include an attachment hole (not illustrated). The attachment hole is a hole (also referred to as a through-hole) extending through the second portion 52 in the Z-direction. In this case, a component (also referred to as an attachment component) for attachment, such as a screw or a bolt, can be placed through the attachment hole to attach the second portions 52 to the attachment destination portion. In other words, the solar cell panel 10 can be attached to the attachment destination portion. In the example in FIGS. 1 and 2, the solar cell panel 10 includes the supports 5 respectively at its end in the negative X-direction as the fourth direction and its end in the positive X-direction as the second direction. Thus, the two supports 5 at two ends of the solar cell panel 10 in the X-direction can be fixed to the attachment destination portion. This allows the solar cell panel 10 to be firmly attached to the attachment destination portion. The supports 5 thus serve as members (also referred to as attachment members) for attaching the solar cell panel 10 to an attachment destination object. The solar cell module 100 including the supports 5 can thus be easily and stably fixed to the attachment destination portion.

In the first embodiment, the supports 5 are mainly not located at two sides of the solar cell panel 10 in the Y-direction. More specifically, the supports 5 are not substantially located at an end (also referred to as a first end) E1 of the solar cell panel 10 in the negative Y-direction or an end (also referred to as a second end) E2 of the solar cell panel 10 in the positive Y-direction. Each of the first end E1 and the second end E2 is an end in the X direction. Thus, as illustrated in FIG. 7, under an external force F1 applied to the supports 5, the solar cell panel 10 can bend in an arc when viewed in the positive Y-direction. For example, the solar cell panel 10 can bend in an arc with a radius of about several hundred millimeters. In this example, the arc with a radius of about several hundred millimeters may be an arc with a radius of about 500 millimeters. The solar cell panel 10 can thus be easily attached to a curved attachment destination portion.

### 1-1-6. Shape of Solar Cell Element

As illustrated in at least one of FIG. 2 or FIG. 3, for example, each of the multiple solar cell elements 31 in the solar cell 3 includes the first element surface 31f curving convexly. For example, each of the multiple solar cell elements 31 in the solar cell 3 includes the second element surface 31s curving concavely. In other words, each of the solar cell elements 31 being plates curves convexly toward the second surface 1s of the first protective layer 1. For example, each of the first element surface 31f and the second element surface 31s curves in an arc along an imaginary arc with a radius of about several hundred to several thousand millimeters.

For example, for each of the solar cell elements 31, one of a YZ cross section or an XZ cross section curves convexly toward the second surface 1s. For each of the solar cell elements 31, the YZ cross section is an imaginary cross section taken in the negative Y-direction as the first direction and in the negative Z-direction as the third direction with respect to the solar cell elements 31. For each of the solar cell elements 31, the XZ cross section is an imaginary cross section taken in the positive X-direction as the second direction and in the negative Z-direction as the third direction with respect to the solar cell elements 31.

For example, as illustrated in FIG. 2, the first element surface 31f has the XZ cross section curving convexly toward the second surface 1s. The second element surface 31s has the XZ cross section curving concavely toward the second surface 1s. The XZ cross section of the first element surface 31f is an imaginary cross section taken in the positive X-direction as the second direction and in the negative Z-direction as the third direction with respect to the first element surface 31f. The XZ cross section of the second element surface 31s is an imaginary cross section taken in the positive X-direction as the second direction and in the negative Z-direction as the third direction with respect to the second element surface 31s. In this case, for example, the first element surface 31f curves convexly along a first imaginary arc surface. The first imaginary arc surface is an imaginary curved surface defined by extending, in the negative Y-direction as the first direction, an arc curving convexly in the positive Z-direction opposite to the negative Z-direction as the third direction on the XZ plane. The XZ plane is an imaginary plane extending in the positive X-direction as the second direction and in the negative Z-direction as the third direction. For example, the second element surface 31s curves concavely along a second imaginary arc surface. The second imaginary arc surface is an imaginary curved surface defined by extending, in the negative Y-direction as the first direction, an arc curving convexly in the positive Z-direction opposite to the negative Z-direction as the third direction on the XZ plane. The second imaginary arc surface is located along, for example, the first imaginary arc surface.

For example, as illustrated in FIG. 3, the first element surface 31f may have the YZ cross section curving convexly toward the second surface 1s. The second element surface 31s may have the YZ cross section curving concavely toward the second surface 1s. In this case, for example, the first element surface 31f curves convexly along a third imaginary arc surface. The third imaginary arc surface is an imaginary curved surface defined by extending, in the positive X-direction as the second direction, an arc curving convexly in the positive Z-direction opposite to the negative Z-direction as the third direction on a YZ plane. The YZ plane is an imaginary plane extending in the negative Y-direction as the first direction and in the negative Z-direction as the third direction. For example, the second element surface 31s curves concavely along a fourth imaginary arc surface. The fourth imaginary arc surface is an imaginary curved surface defined by extending, in the positive X-direction as the second direction, an arc curving convexly in the positive Z-direction opposite to the negative Z-direction as the third direction on the YZ plane. The fourth imaginary arc surface is located along, for example, the third imaginary arc surface.

For example, for each of the solar cell elements 31, both the YZ cross section and the XZ cross section may curve convexly toward the second surface 1s. In this case, for example, each of the solar cell elements 31 may curve along an imaginary spherical surface. More specifically, for example, the first element surface 31f may curve convexly along a portion of a first imaginary spherical surface, and the second element surface 31s may curve concavely along a portion of a second imaginary spherical surface. The second imaginary spherical surface is located along, for example, the first imaginary spherical surface. Each of the first imaginary spherical surface and the second imaginary spherical surface has a radius of, for example, about several hundred to several thousand millimeters.

### 1-2. Characteristics of Solar Cell Module

In the first embodiment, the first protective layer 1 is made of a light-transmissive resin. Thus, the first protective layer 1 can be thinner, allowing the solar cell module 100 to be lighter.

When various objects such as falling objects and flying objects hit the first protective layer 1 that is thinner, the shock caused by each of the hitting objects may be transmitted to the solar cell elements 31 more easily.

In the first embodiment, however, the first element surface 31f facing the second surface 1s of the first protective layer 1 curves convexly in each of the solar cell elements 31 in the solar cell 3. Additionally, for example, the second element surface 31s opposite to the first element surface 31f curves concavely in each of the solar cell elements 31 in the solar cell 3. In other words, each of the solar cell elements 31 being plates curves convexly toward the second surface 1s of the first protective layer 1.

In this example, the solar cell elements 31 curving convexly toward the first protective layer 1 can reduce shock to the solar cell elements 31 when various objects such as falling objects and flying objects hit the first protective layer 1. The solar cell elements 31 are thus less likely to break. In other words, the solar cell elements 31 can have higher impact resistance. The power generation efficiency of the solar cell module 100 is thus less likely to be reduced. Thus, the solar cell module 100 can both be lighter and have higher power generation efficient. In other words, the solar cell module 100 can be lighter and have higher power generation efficiency.

In other words, the solar cell elements 31 curving convexly toward the first protective layer 1 can improve the impact resistance of the solar cell elements 31. Thus, the first protective layer 1 can be thinner, allowing the solar cell module 100 to be lighter. Thus, for example, the solar cell module 100 can both be lighter and have higher power generation efficiency.

### 1-3. Method for Manufacturing Solar Cell Element

An example method for manufacturing the solar cell elements 31 will now be described with reference to FIGS. 6 and 8 to 12. For example, each of the solar cell elements 31 can be manufactured by performing processes in the order of preparing the semiconductor substrate 310, forming a textured structure, forming the second conductivity type area 310s, forming the passivation film 316, forming the anti-reflection film 317, forming the protective film 318, and forming electrodes.

### Preparation of Semiconductor Substrate

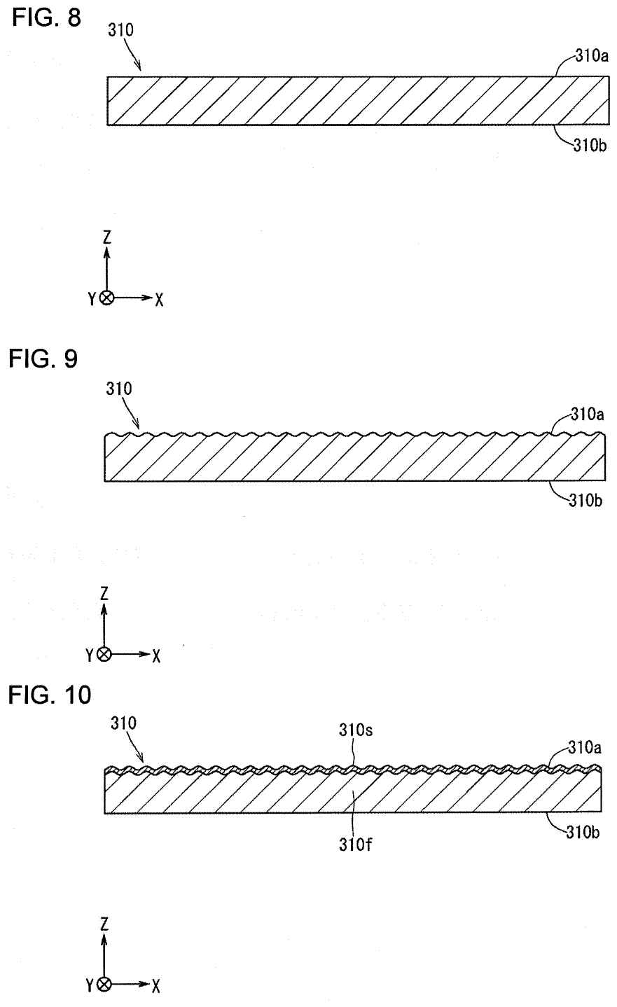

For example, the semiconductor substrate 310 is prepared as illustrated in FIG. 8. The semiconductor substrate 310 includes a first surface 310a and a second surface 310b opposite to the first surface 310a. The semiconductor substrate 310 may be, for example, formed with a known method such as the Czochralski (CZ) method or molding. In this example, a polycrystalline silicon ingot of p-type as the first conductivity type is manufactured by molding. The ingot is sliced to have an intended thickness of, for example, less than or equal to 250 μm to manufacture the semiconductor substrate 310. In this state, for example, a surface of the semiconductor substrate 310 may be slightly etched with an aqueous solution such as sodium hydroxide, potassium hydroxide, or fluoronitric acid to remove, from a cut surface of the semiconductor substrate 310, a layer that has been mechanically damaged and a layer that has been contaminated.

### Formation of Textured Structure

For example, as illustrated in FIG. 9, fine protrusions and recesses (also referred to as a textured structure) are formed in the first surface 310a of the semiconductor substrate 310. The textured structure can be formed by wet or dry etching. Wet etching may be performed with, for example, an alkaline aqueous solution such as sodium hydroxide or an acid aqueous solution such as fluoronitric acid. Dry etching may be performed by, for example, reactive ion etching (RIE).

### Formation of Second Conductivity Type Area

For example, as illustrated in FIG. 10, the second conductivity type area 310s that is a conductor area of n-type as the second conductivity type is formed on the first surface 310a of the semiconductor substrate 310 with the textured structure. More specifically, the second conductivity type area 310s that is the conductor area of n-type as the second conductivity type is formed on the surface layer of the semiconductor substrate 310 adjacent to the first surface 310a with the textured structure. The second conductivity type area 310s may be formed by, for example, an application and thermal diffusion method or vapor phase thermal diffusion. For the application and thermal diffusion method, for example, a diphosphorus pentaoxide (P₂O₅) paste is applied to a surface of the semiconductor substrate 310, and phosphorus undergoes thermal diffusion. For vapor phase thermal diffusion, for example, a gaseous phosphorus oxychloride (POCl₃) is used as a diffusion source. When, for example, the second conductivity type area 310s has also been formed on the second surface 310b of the semiconductor substrate 310, the second conductivity type area 310s formed on the second surface 310b is removed by etching with an aqueous solution of fluoronitric acid. Subsequently, for example, phosphorus glass that has adhered to the first surface 310a of the semiconductor substrate 310 in forming the second conductivity type area 310s is removed by etching. Alternatively, for example, a diffusion mask may be preformed on the second surface 310b of the semiconductor substrate 310 and removed after the second conductivity type area 310s is formed by, for example, vapor phase thermal diffusion.

### Formation of Passivation Film

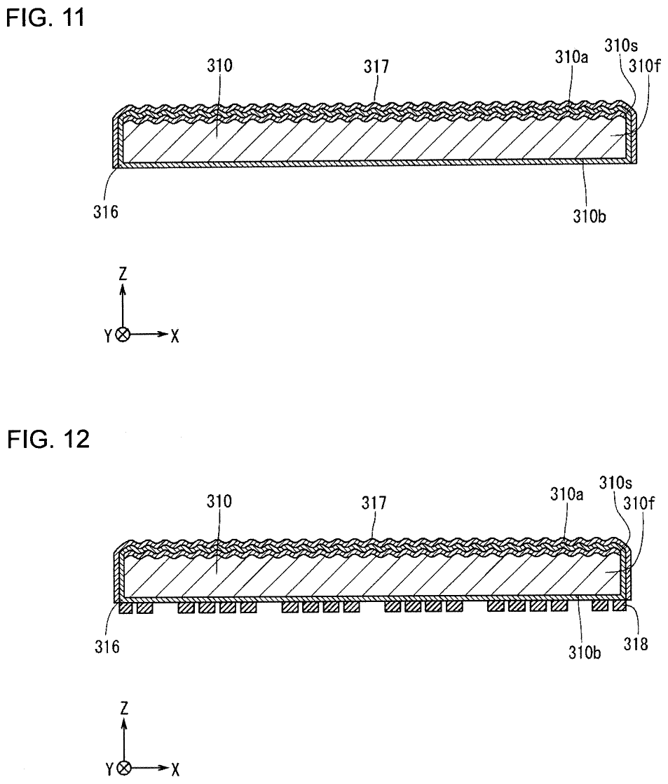

For example, the passivation film 316 is formed at least on the second surface 310b of the semiconductor substrate 310. For example, as illustrated in FIG. 11, the passivation film 316 is formed on each of the second surface 310b and the first surface 310a of the semiconductor substrate 310. The passivation film 316 may be, for example, a film mainly containing aluminum oxide.

The passivation film 316 may be formed by, for example, atomic layer deposition (ALD). By ALD, the passivation film 316 may be formed on the entire periphery of the semiconductor substrate 310 including end faces. In the process of forming the passivation film 316 by ALD, the semiconductor substrate 310 with the second conductivity type area 310s formed is first placed in a chamber in a film deposition device. The semiconductor substrate 310 is then heated to a temperature range of about 100 to 250° C. In this state, processes A to D described below are repeated multiple times to form the passivation film 316 mainly containing aluminum oxide. This forms the passivation film 316 with an intended thickness.

### Process A

An aluminum raw material such as trimethylaluminum (TMA) to form an aluminum oxide layer is supplied on the semiconductor substrate 310 together with a carrier gas such as an Ar gas or a nitrogen gas. The aluminum raw material is thus adsorbed in the entire periphery of the semiconductor substrate 310. TMA is supplied for, for example, about 15 to 3000 milliseconds. At the start of process A, for example, surfaces of the semiconductor substrate 310 have a terminal end with a hydroxyl group (OH group). In this case, the surfaces of the semiconductor substrate 310 have a structure of Si—O—H. This structure may be formed by performing, for example, processing of the semiconductor substrate 310 with dilute hydrofluoric and washing of the semiconductor substrate 310 with pure water in this order.

### Process B

The chamber in the film deposition device is purified with a nitrogen gas. In this process, the aluminum raw material in the chamber is removed. Of the aluminum raw material physically and chemically absorbed by the semiconductor substrate 310, the aluminum raw material excluding components absorbed in an atomic layer is also removed. The duration for purifying the chamber with a nitrogen gas is set to, for example, about one to several tens of seconds.

### Process C

An oxidizing agent such as water or an ozone gas is supplied into the chamber in the film deposition device. The alkyl group in the TMA is thus removed and replaced with the OH group. This forms an aluminum oxide atomic layer on the semiconductor substrate 310. The duration for supplying the oxidizing agent into the chamber is set to, for example, about 750 to 1100 milliseconds. In this process, for example, hydrogen may be supplied together with the oxidizing agent to cause the aluminum oxide to contain a hydrogen atom.

### Process D

The chamber in the film deposition device is purified with a nitrogen gas. This removes the oxidizing agent in the chamber. In this process, for example, the oxidizing agent that has not reacted in forming the aluminum oxide atomic layer on the semiconductor substrate 310 is removed. The duration for purifying the chamber with a nitrogen gas is set to, for example, about one to several tens of seconds.

### Formation of Anti-reflection Film

For example, as illustrated in FIG. 11, the anti-reflection film 317 is formed on the passivation film 316. The anti-reflection film 317 is, for example, a silicon nitride film.

The anti-reflection film 317 may be formed by, for example, plasma-enhanced chemical vapor deposition (PECVD) or sputtering. When PECVD is used, the semiconductor substrate 310 is preheated to a temperature higher than the temperature of the anti-reflection film 317 during deposition. The reaction pressure is then set to about 50 to 200 Pa. Plasma is generated with glow discharge decomposition using a mixed gas of silane and ammonia diluted with a nitrogen gas to be deposited on the heated semiconductor substrate 310. This forms the non-reflection film 317 on the semiconductor substrate 310. In this example, the film deposition temperature is set to about 350 to 650° C. The temperature for preheating the semiconductor substrate 310 is about 50° C. higher than the film deposition temperature. The frequency of a radio-frequency power supply for glow discharge is about 10 to 500 kHz. The flow rate of the gas is determined as appropriate for, for example, the size of the reactor chamber. For example, the flow rate of the gas is set in a range of about 150 to 6000 milliliters per minute. In this example, the value obtained by dividing a flow rate B of the ammonia gas by a flow rate A of the silane gas (B/A) is set to a range of 0.5 to 1.5.

### Formation of Protective Film

For example, as illustrated in FIG. 12, the protective film 318 is formed in an intended pattern at least on a surface of the passivation film 316 adjacent to the second surface 310b of the semiconductor substrate 310. The intended pattern includes many through-holes. The protective film 318 may be formed by, for example, wet or dry processing. The wet processing is, for example, applying a solution. The dry processing is, for example, PECVD or sputtering.

When, for example, a wet processing that applies a solution is used, a solution is applied in the intended pattern at least to the surface of the passivation film 316 adjacent to the second surface 310b of the semiconductor substrate 310 and then dried to form the protective film 318. The intended pattern includes many through-holes. The solution is, for example, an insulating paste. The insulating paste contains, for example, a siloxane resin as a raw material of the protective film 318, an organic solvent, and multiple fillers. The siloxane resin is a siloxane compound with a siloxane bond (Si—O—Si bond). For example, the siloxane resin is a resin with a low molecular weight generated through hydrolysis and subsequent condensation polymerization of, for example, alkoxysilane or silazane. The resin has a molecular weight of less than or equal to 15000. The solution may be applied by, for example, screen printing. The applied solution may be dried using, for example, a hot plate or a drying furnace.

### Formation of Electrodes

For example, as illustrated in FIG. 6, electrodes including the first electrodes 311, the second electrodes 312, the third electrodes 313, and the fourth electrode 314 are formed.

For example, a material (also referred to as a first electrode material) for forming the first electrodes 311 and the second electrodes 312 is placed in an intended pattern on a surface of the semiconductor substrate 310 adjacent to the first surface 310a. More specifically, for example, the first electrode material is placed in an intended pattern on the anti-reflection film 317 formed on the first surface 310a. The first electrode material is then heated to form the first electrodes 311 and the second electrodes 312. The fifth electrodes 315 may be formed together with the second electrodes 312.

In the first embodiment, for example, the first electrode material is a silver paste. In this case, the first electrode material is placed by, for example, applying the silver paste. The silver paste may be applied by, for example, screen printing. The applied silver paste may be dried at a predetermined temperature to evaporate a solvent in the silver paste. The silver paste is then, for example, fired in a firing furnace at a maximum temperature of about 600 to 850° C. for a heating duration of about several tens of seconds to several tens of minutes. This forms the first electrodes 311 and the second electrodes 312.

For example, materials (also referred to as second electrode materials) for forming the third electrodes 313 and the fourth electrode 314 are placed in an intended pattern on a surface of the semiconductor substrate 310 adjacent to the second surface 310b. More specifically, for example, the materials (also referred to as the second electrode materials) for forming the third electrodes 313 and the fourth electrode 314 are placed on the protective film 318, in the many through-holes in the protective film 318, and in the multiple holes in the protective film 318. The second electrode materials are then heated to form the third electrodes 313 and the fourth electrode 314.

In the first embodiment, the second electrode materials are, for example, a silver paste and an aluminum paste. In this case, the second electrode materials are placed by, for example, applying the silver paste and the aluminum paste. The silver paste and the aluminum paste may be applied by, for example, screen printing. For example, the silver paste is applied to portions of the semiconductor substrate 310 adjacent to the second surface 310b in an intended pattern. More specifically, for example, the silver paste is applied to the passivation film 316 exposed through the multiple holes in the protective film 318. Additionally, for example, the aluminum paste is applied to portions of the semiconductor substrate 310 adjacent to the second surface 310b in an intended pattern to come in contact with parts of the applied silver paste. More specifically, for example, the aluminum paste is applied to the protective film 318 on the second surface 310b, to the many through-holes in the protective film 318, and to parts of the applied silver paste. The applied silver paste and the applied aluminum paste may be dried at a predetermined temperature to evaporate solvents in the silver paste and the aluminum paste. The silver paste and the aluminum paste are then, for example, fired in a firing furnace at a maximum temperature of about 600 to 850° C. for a heating duration of about several tens of seconds to several tens of minutes. This forms the third electrodes 313 and the fourth electrode 314. When fired, the aluminum paste placed in the many through-holes in the protective film 318 fires through the passivation film 316 to form the BSFs 310t in a surface layer of the first conductivity type area 310f. In this example, the third electrodes 313 and the fourth electrode 314 may be formed simultaneously, the fourth electrode 314 may be formed after the third electrodes 313 are formed, or the third electrodes 313 may be formed after the fourth electrode 314 is formed.

In this example, the metal pastes may be fired simultaneously after application to form the first electrodes 311, the second electrodes 312, the third electrodes 313, and the fourth electrode 314.

For example, silicon, which is the main component of the semiconductor substrate 310, has a linear expansion coefficient of 2.60×10⁻⁶ (1/° C.). For example, silver, which is the main component of the first electrodes 311, the second electrodes 312, the third electrodes 313, and the fifth electrodes 315, has a linear expansion coefficient of 1.89×10⁻⁵ (1/° C.). For example, aluminum, which is the main component of the fourth electrode 314, has a linear expansion coefficient of 2.31×10⁻⁵ (1/° C.). In other words, silver and aluminum have linear expansion coefficients that are greater than silicon, but do not greatly differ from each other. Thus, the first electrodes 311, the second electrodes 312, the third electrodes 313, the fourth electrode 314, and the fifth electrodes 315 have a greater shrinkage rate than the semiconductor substrate 310 when cooled in the process (also referred to as an electrode formation process) of firing the silver paste and the aluminum paste to form the first electrodes 311, the second electrodes 312, the third electrodes 313, the fourth electrode 314, and the fifth electrodes 315.

Additionally, for example, as illustrated in FIGS. 4 and 5, the areas of the third electrodes 313 and the fourth electrode 314 when the second element surface 31s is viewed in plan are notably larger than the areas of the first electrodes 311, the second electrodes 312, and the fifth electrodes 315 when the first element surface 31f is viewed in plan. In particular, for example, the area of the fourth electrode 314 when the second element surface 31s is viewed in plan is notably larger than the areas of the first electrodes 311, the second electrodes 312, and the fifth electrodes 315 when the first element surface 31f is viewed in plan. Thus, in the electrode formation process, the first element surface 31f of each of the solar cell elements 31 curves convexly and the corresponding second element surface 31s curves concavely as the fourth electrode 314 with a larger area shrinks when cooled. Each of the solar cell elements 31 is thus manufactured with the first element surface 31f curving convexly and the second element surface 31s curving concavely.

### 1-4. Example Method for Manufacturing Solar Cell Module

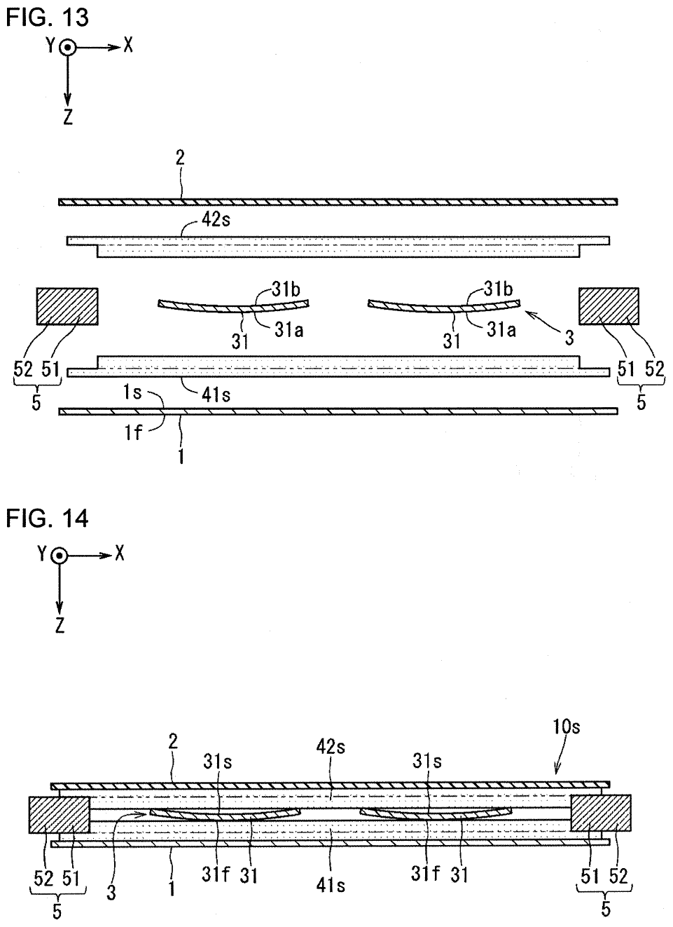

An example method for manufacturing the solar cell module 100 according to the first embodiment will now be described with reference to FIGS. 13 and 14.

The first protective layer 1 is prepared first. For the first protective layer 1, for example, rectangular front and back surfaces and a resin film that is light-transmissive and weather-resistant are prepared. The light-transmissive and weather-resistant resin is, for example, a fluorine-based resin. The fluorine-based resin is, for example, FEP, ETFE, or ECTFE. In this state, for example, the second surface Is being a surface of the first protective layer 1 undergoes a treatment such as corona treatment or plasma treatment to activate the surface. This can improve the adhesion between the first protective layer 1 and the filler 4 in a lamination process (described later).

Subsequently, for example, as illustrated in FIGS. 13 and 14, the first protective layer 1, a first sheet 41s, the solar cell 3, the supports 5, a second sheet 42s, and the second protective layer 2 are stacked in this order to form a stack 10s.

In the stack 10s, the solar cell 3 is located between the two supports 5. More specifically, in the stack 10s, the first support 5, the solar cell 3, and the second support 5 are spaced from one another in the X-direction. In the stack 10s, for example, a portion of each of the third wires 34 in the solar cell 3 extends outside the stack 10s to be connected to, for example, a terminal box outside the solar cell panel 10.

The first sheet 41s is a resin sheet to be the first filler 41. The material for the resin sheet is, for example, EVA. In the stack 10s, the first sheet 41s is located between the first protective layer 1 and the solar cell 3 and between the first protective layer 1 and the supports 5. In other words, in the stack 10s, the first sheet 41s is located on the first protective layer 1, and the solar cell 3 and the supports 5 are located on the first sheet 41s. The first sheet 41s is rectangular when viewed in plan. In the stack 10s, the first sheet 41s may include, for example, portions (also referred to as first sheet portions) with a smaller thickness located between the first protective layer 1 and the respective supports 5 and a portion (also referred to as a second sheet portion) with a greater thickness located at least partially between the two supports 5. The first sheet 41s may be a single sheet, or may include two or more sheets stacked on one another. For example, each of the first sheet portions may be a single sheet, and the second sheet portion may be a stack of two or more sheets.

The second sheet 42s is a resin sheet to be the second filler 42. The material for the resin sheet is, for example, EVA. The second sheet 42s may contain a pigment. In the stack 10s, the second sheet 42s is located between the second protective layer 2 and the solar cell 3 and between the second protective layer 2 and the supports 5. In other words, in the stack 10s, two ends of the second sheet 42s face the respective supports 5. The second sheet 42s is rectangular when viewed in plan. In the stack 10s, the second sheet 42s may include, for example, portions (also referred to as third sheet portions) with a smaller thickness located between the second protective layer 2 and the respective supports 5 and a portion (also referred to as a fourth sheet portion) with a greater thickness located at least partially between the two supports 5. The second sheet 42s may be a single sheet, or may include two or more sheets stacked on one another. For example, each of the third sheet portions may be a single sheet, and the fourth sheet portion may be a stack of two or more sheets.

In the stack 10s, the second protective layer 2 is located on the second sheet 42s.

Subsequently, for example, the stack 10s undergoes laminating. Laminating integrates the stack 10s using, for example, a laminating device (also referred to as a laminator). In the laminator, for example, the stack 10s is placed on a heater plate in a chamber. The inside of the chamber is then depressurized to about 50 to 150 Pa, while the stack 10s is being heated to about 100 to 200° C. The heating causes the first sheet 41s and the second sheet 42s to have a certain level of flowability. In this state, the stack 10s is pressed in the positive Z-direction in the chamber with a pressing member such as a diaphragm sheet and is thus integrated. The solar cell panel 10 can thus be obtained.

A terminal box may be attached to the solar cell panel 10 as appropriate after laminating. In this case, for example, the portion of each of the third wires 34 extending outside the solar cell panel 10 from the solar cell 3 is connected to a terminal in the terminal box as appropriate. The solar cell module 100 according to the first embodiment can thus be manufactured.

In the above example, the solar cell panel 10 including the supports 5 can be obtained by laminating. The solar cell panel 10 and the solar cell module 100 can thus be manufactured more easily than a structure in which an external frame (not illustrated) is attached to the solar cell panel 10 with, for example, screws in place of the supports 5.

### 1-5. Overview of First Embodiment

In the solar cell module 100 according to the first embodiment, for example, the first protective layer 1 is made of a light-transmissive resin. Thus, the first protective layer 1 can be thinner, allowing the solar cell module 100 to be lighter. Additionally, for example, each of the solar cell elements 31 in the solar cell 3 includes the first element surface 31f curving convexly and the second element surface 31s curving concavely. For example, the solar cell elements 31 curving convexly toward the first protective layer 1 can reduce shock to the solar cell elements 31 when various objects such as falling objects and flying objects hit the first protective layer 1. The solar cell elements 31 are thus less likely to break. The power generation efficiency of the solar cell module 100 is thus less likely to be reduced. Thus, the solar cell module 100 can be lighter and have higher power generation efficiency.

### 1-6. Arrangement Number of Solar Cell Elements

In the example in FIG. 1, the number (also referred to as an arrangement number) of solar cell elements 31 arranged in the X-direction is two as an even number. In other words, the arrangement number of solar cell elements 31 in a direction orthogonal to the longitudinal direction of the supports 5 is an even number. The solar cell elements 31 have the same or substantially the same width in the X-direction. Thus, no solar cell elements 31 are located at the middle of the solar cell panel 10 in the X-direction. In other words, the solar cell panel 10 has its middle in the X-direction located between two solar cell elements 31 adjacent to each other in the X-direction.

For example, when bending under the external force F1 as illustrated in FIG. 7, the solar cell panel 10 receives a relatively large stress at its middle in the X-direction. Additionally, for example, with the supports 5 attached to the attachment destination portion, the solar cell panel 10 may receive a load applied from, for example, snow accumulated on the front surface 10f of the solar cell panel 10. In this case as well, the solar cell panel 10 can bend in an arc when viewed in the positive Y-direction. The solar cell panel 10 receives a relatively large stress at its middle in the X-direction.

In contrast, in the example in FIG. 1, the solar cell panel 10 includes no solar cell elements 31 at its middle in the X-direction. Thus, when the solar cell panel 10 bends under the external force F1 or a load applied from, for example, accumulated snow, each of the solar cell elements 31 receives a relatively small stress. The solar cell elements 31 are thus less likely to break. The power generation efficiency of the solar cell module 100 is thus less likely to be reduced.

### 2. Other Embodiments

The present disclosure is not limited to the above first embodiment and may be changed or altered variously without departing from the spirit and scope of the present disclosure.

### 2-1. Second Embodiment

### 2-1-1. Solar Cell Module

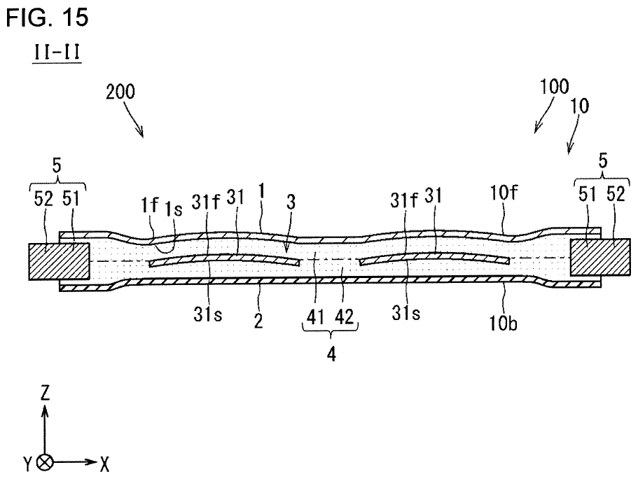

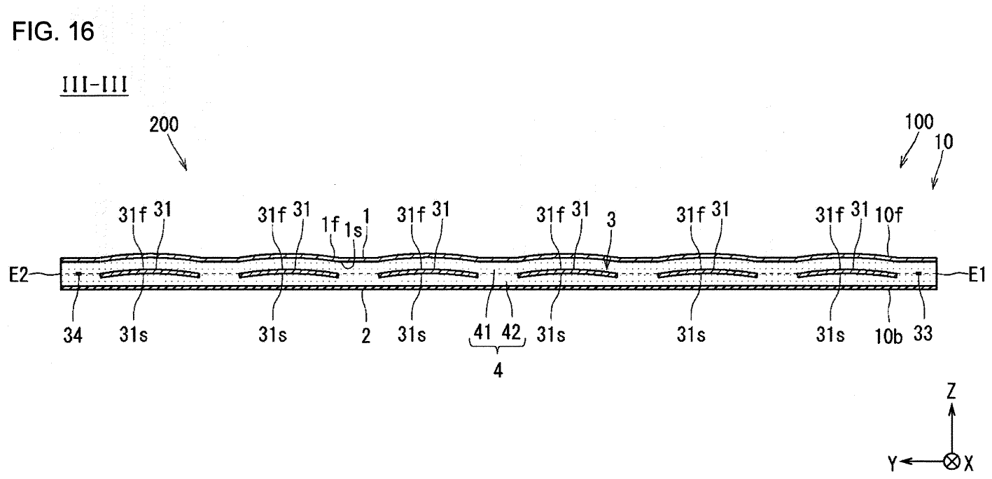

In the above first embodiment, as illustrated in at least one of FIG. 15 or FIG. 16, for example, the first surface If may curve convexly following the first element surface 31f of each of the multiple solar cell elements 31 in the solar cell 3. Note that the first surface 1f curving convexly following the first element surface 31f may have the same curvature as the first element surface 31f, or a curvature slightly different from the first element surface 31f.

When, for example, used outdoors for power generation, the solar cell module 100 is installed with the first surface 1f facing upward or obliquely upward. In a second embodiment, for example, portions of the first surface 1f curve convexly following the respective solar cell elements 31. Thus, for example, rainwater easily flows along the convex first surface 1f and is less likely to accumulate on areas of the first surface 1f above the solar cell elements 31. This can reduce, for example, the amount of rainwater to dry on the areas of the first surface 1f above the solar cell elements 31. Thus, for example, dust and mud in rainwater are less likely to adhere to the areas of the first surface 1f above the solar cell elements 31. In other words, for example, the areas of the first surface 1f above the solar cell elements 31 are less likely to be soiled. Thus, for example, sunlight entering the solar cell elements 31 is less likely to be blocked by dirt on the first surface 1f. Thus, for example, the solar cell module 100 can have higher power generation efficiency.

In the second embodiment, for example, each of the portions of the first surface 1f following their respective first element surfaces 31f curves in an arc along an imaginary arc with a radius of about several hundred to several thousand millimeters.

For example, for each of the portions of the first surface 1f following the respective first element surfaces 31f, one of the YZ cross section or the XZ cross section curves convexly in a direction away from the corresponding first element surface 31f. In the present disclosure, the direction away from the first element surface 31f is, for example, a direction from the first element surface 31f toward the second surface 1s, or the positive Z-direction opposite to the negative Z-direction as the third direction. For each of the portions of the first surface 1f following the respective first element surfaces 31f, the YZ cross section is an imaginary cross section taken in the negative Y-direction as the first direction and in the negative Z-direction as the third direction with respect to the portion. For each of the portions of the first surface 1f following the respective first element surfaces 31f, the XZ cross section is an imaginary cross section taken in the positive X-direction as the second direction and in the negative Z-direction as the third direction with respect to the portion.

For example, as illustrated in FIG. 15, each of the portions of the first surface 1f following the respective first element surfaces 31f has the XZ cross section curving convexly in the direction away from the corresponding first element surface 31f. In this case, for example, each of the portions of the first surface 1f following the respective first element surface 31f curves convexly along a fifth imaginary arc plane. The fifth imaginary arc surface is an imaginary curved surface defined by extending, in the negative Y-direction as the first direction, an arc protruding in the positive Z-direction opposite to the negative Z-direction as the third direction on the XZ plane.

For example, as illustrated in FIG. 16, each of the portions of the first surface 1f following the respective first element surfaces 31f has the YZ cross section curving convexly in the direction away from the corresponding first element surface 31f. In this case, for example, each of the portions of the first surface 1f following the respective first element surfaces 31f curves convexly along a sixth imaginary arc surface. The sixth imaginary arc surface is an imaginary curved surface defined by extending, in the positive X-direction as the second direction, an arc protruding in the positive Z-direction opposite to the negative Z-direction as the third direction on the YZ plane.

For example, for each of the portions of the first surface 1f following the respective first element surfaces 31f, both the YZ cross section and the XZ cross section may curve convexly in the direction away from the corresponding first element surface 31f. In this case, for example, each of the portions of the first surface 1f following the respective first element surfaces 31f may curve along an imaginary spherical surface. More specifically, for example, each of the portions of the first surface 1f following the respective first element surfaces 31f may curve convexly along a portion of a third imaginary sphere. The third imaginary sphere has a radius of, for example, about several hundred to several thousand millimeters.

### 2-1-2. Specific Example Method for Manufacturing Solar Cell Module

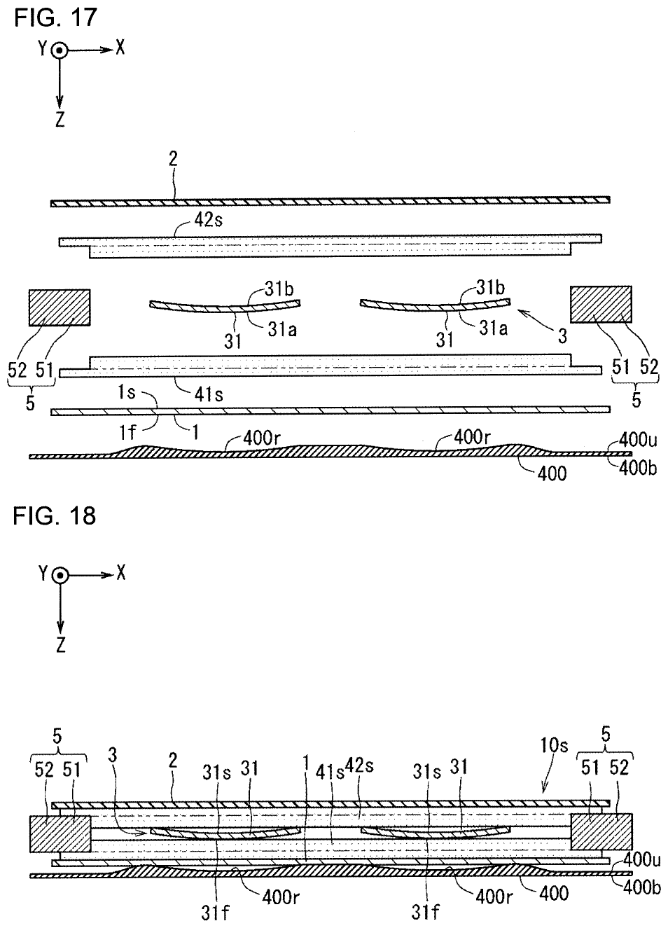

An example method for manufacturing a solar cell module 100 according to the second embodiment will now be described with reference to FIGS. 17 and 18.

In this example, based on the method for manufacturing the solar cell module 100 according to the first embodiment, for example, the first protective layer 1, the first sheet 41s, the solar cell 3 and the supports 5, the second sheet 42s, and the second protective layer 2 are stacked on a base 400 in this order to form a stack 10s as illustrated in FIGS. 17 and 18.

The base 400 serves as a mold for forming an intended convex shape on the first surface 1f in laminating the stack 10s. The base 400 includes, for example, a plate member including a flat lower surface 400b and an upper surface 400u with an intended convex and concave pattern. The upper surface 400u includes, for example, a concave portion 400r. In the example in FIGS. 17 and 18, the upper surface 400u includes multiple concave portions 400r. Each of the concave portions 400r has a concave shape corresponding to the convex shape of the first surface 1f formed through laminating. The material for the base 400 is, for example, glass or metal. The base 400 may be manufactured by various processing methods including, for example, dissolving a glass plate with a chemical solution, or grinding or polishing a glass plate or a metal plate.

To laminate the stack 10s, for example, the base 400 on which the stack 10s is placed is placed on a heater plate in a chamber in a laminator as illustrated in FIG. 18. In this state, the stack 10s is heated while the air pressure in the chamber in the laminator is being reduced. The stack 10s is then pressed in the positive Z-direction with a pressing member such as a diaphragm sheet. This integrates the stack 10s. The first protective layer 1 deforms and the first sheet 41s and the second sheet 42s flow based on the convex and concave shapes of the upper surface 400u of the base 400. This causes the first protective layer 1 to have the first surface 1f curving convexly following the first element surface 31f of each of the multiple solar cell elements 31. The solar cell panel 10 according to the second embodiment can thus be obtained. Subsequently, for example, a terminal box is attached to the solar cell panel 10, and portions of the third wires 34 are connected to terminals in the terminal box. The solar cell module 100 according to the second embodiment can thus be manufactured.

### 2-2. Third Embodiment

### 2-2-1. Solar Cell Module

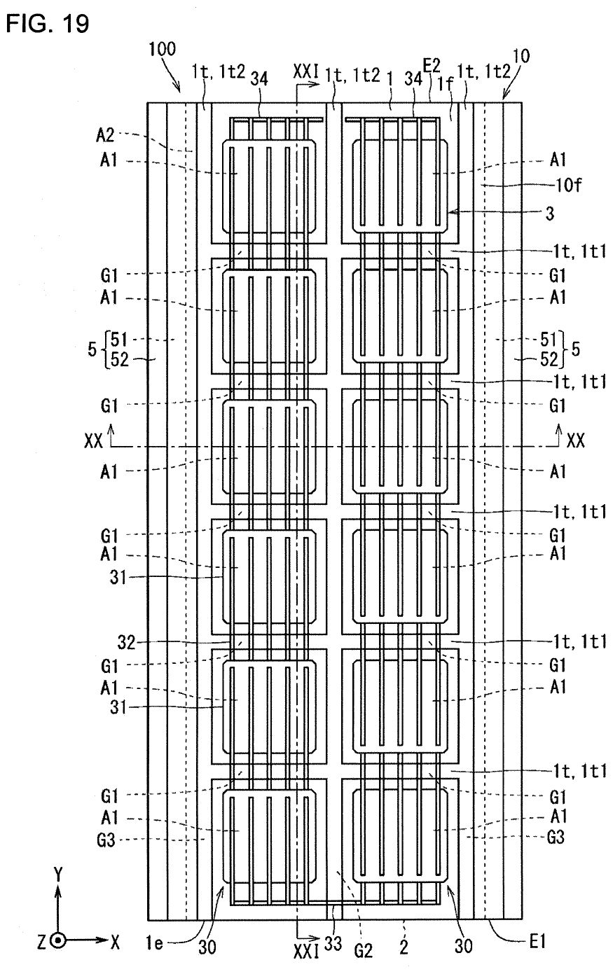

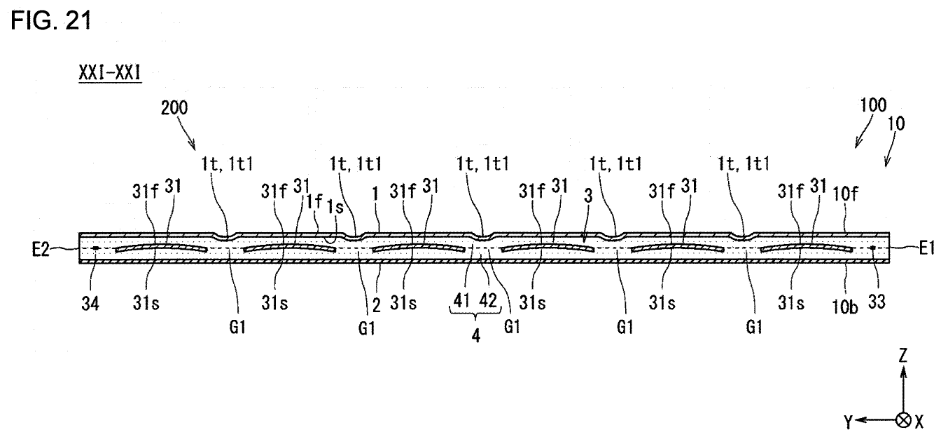

In the above first embodiment, as illustrated in FIGS. 19 to 21, for example, the first surface 1f may include first areas A1 and a second area A2, and may also include one or more linear recesses 1t in the second area A2 when viewed in plan. The first areas A1 are areas of the first surface 1f located above the multiple solar cell elements 31 when the first surface 1f is viewed in plan. In other words, the first areas A1 are areas of the first surface 1f overlapping the multiple solar cell elements 31 when the solar cell module 100 is viewed in plan from the first surface 1f. The second area A2 is an area of the first surface 1f different from the first areas A1 when the first surface 1f is viewed in plan. In other words, the second area A2 is an area of the first surface 1f not located above the multiple solar cell elements 31 when the first surface 1f is viewed in plan. In still other words, the second area A2 is an area of the first surface 1f not overlapping the multiple solar cell elements 31 when the solar cell module 100 is viewed in plan from the first surface 1f. Each of the linear recesses 1t is, for example, an elongated linear recess. The elongated linear recesses may not be linear, and may curve. The linear recesses are recessed toward the filler 4 with respect to the respective first areas A1. In other words, the linear recesses 1t are, for example, recessed in the negative Z-direction as the third direction with respect to the respective first areas A1. Each of the linear recesses 1t has a depth of, for example, about 0.1 to 2 mm with respect to the corresponding first areas A1. In the example in FIGS. 19 and 21, the solar cell module 100 according to the first embodiment additionally includes one or more linear recesses 1t as an example solar cell module 100 according to a third embodiment.

When, for example, the solar cell module 100 is used outdoors for power generation, the solar cell module 100 may be installed with the first surface 1f facing obliquely upward. More specifically, for example, the solar cell module 100 may be installed with the first end E1 located diagonally downward and the second end E2 located diagonally upward. In the solar cell module 100 according to the third embodiment, for example, the first surface 1f includes one or more linear recesses 1t located on portions other than above the multiple solar cell elements 31. Thus, for example, rainwater easily flows through the one or more linear recesses 1t on the first surface 1f and is less likely to accumulate on the first areas A1 of the first surface 1f located above the solar cell elements 31. This can reduce, for example, the amount of rainwater to dry on the first areas A1 of the first surface 1f. Thus, for example, dust and mud in rainwater are less likely to adhere to the first areas A1 on the first surface 1f. In other words, for example, the first surface 1f of the solar cell module 100 is less likely to be soiled in the first areas A1 of the first surface 1f. Thus, for example, sunlight entering the solar cell elements 31 is less likely to be blocked by dirt on the first surface 1f. Thus, for example, the solar cell module 100 can have higher power generation efficiency.

In this example, the one or more linear recesses 1t may be located along gaps between the multiple solar cell elements 31 when the first surface 1f is viewed in plan. For example, the one or more linear recesses 1t may be located along the outer peripheries of the solar cell elements 31 not to be located in the first areas A1 above the solar cell elements 31 when the first surface 1f is viewed in plan. For example, the one or more linear recesses 1t may include a first linear recess 1t1 and a second linear recess 1t2 connecting with the first linear recess 1t1.

The first linear recess 1t1 is an elongated linear recess located above a first gap G1 and extending in the positive X-direction as the second direction. The first gap G1 is a gap between two of the solar cell elements 31 arranged in the negative Y-direction as the first direction. More specifically, the gap (first gap) G1 between two of the solar cell elements 31 adjacent to each other in the negative Y-direction as the first direction extends in the positive X-direction as the second direction when viewed in plan. In other words, the first gap G1 has its longitudinal direction aligned with the positive X-direction as the second direction. The first linear recess 1t1 is located above the first gap G1 and extends in the longitudinal direction of the first gap G1 when the first protective layer 1 is viewed in plan. In other words, the first linear recess 1t1 is located above the first gap G1 and extends in the positive X-direction as the second direction when the first protective layer 1 is viewed in plan. The first linear recess 1t1 is a groove located on the first surface 1f and extending in the positive X-direction as the second direction. The first linear recess 1t1 has a depth of, for example, about 0.1 to 2 mm with respect to the first areas A1.

In the example in FIGS. 19 to 21, for the two or more solar cell elements 31 in each of the solar cell strings 30, the first gap G1 is located between every two solar cell elements 31 adjacent to each other in the negative Y-direction as the first direction. More specifically, five first gaps G1 are located for the six solar cell elements 31 in each of the solar cell strings 30. Thus, five first linear recesses 1t1 are located for each of the solar cell strings 30. In the example in FIGS. 19 to 21, two first linear recesses 1t1 located above two first gaps G1 arranged in the positive X-direction as the second direction connect with each other. Thus, two first linear recesses 1t1 located above two first gaps G1 arranged in the positive X-direction as the second direction form a single linear recess extending in the positive X-direction as the second direction. In other words, in the example in FIGS. 19 to 21, five linear recesses extending in the positive X-direction as the second direction are arranged in the negative Y-direction as the first direction. 0

The second linear recess 1t2 is an elongated linear recess extending in the negative Y-direction as the first direction. For example, the second linear recess 1t2 is located above the second gap G2 and extends in the negative Y-direction as the first direction. The second gap G2 is a gap between two of the solar cell elements 31 arranged in the positive X-direction as the second direction. More specifically, the gap (second gap) G2 between two of the solar cell elements 31 adjacent to each other in the positive X-direction as the second direction extends in the negative Y-direction as the first direction. In other words, the second gap G2 has its longitudinal direction aligned with the negative Y-direction as the first direction. The second linear recess 1t2 is located above the second gap G2 and extends in the longitudinal direction of the second gap G2 when the first protective layer 1 is viewed in plan. In other words, the second linear recess 1t2 is located above the second gap G2 and extends in the negative Y-direction as the first direction when the first protective layer 1 is viewed in plan. The second linear recess 1t2 is a groove located on the first surface 1f and extending in the negative Y-direction as the first direction. The second linear recess 1t2 has a depth of, for example, about 0.1 to 2 mm with respect to the first areas A1.

The second gap G2 may be, for example, a gap between two of the solar cell strings 30 adjacent to each other in the positive X-direction as the second direction. In the example in FIGS. 19 to 21, a single second gap G2 is located between the two solar cell strings 30. Thus, a single linear recess 1t2 is located for the two adjacent solar cell strings 30.

Additionally, for example, the second linear recess 1t2 is located above a third gap G3 and extends in the negative Y-direction as the first direction. The third gap G3 is a gap between each of the supports 5 and the solar cell 3 arranged in the positive X-direction as the second direction. More specifically, the gap (third gap) G3 between each of the supports 5 and the solar cell 3 arranged in the positive X-direction as the second direction extends in the negative Y-direction as the first direction. In other words, the third gap G3 has its longitudinal direction aligned with the negative Y-direction as the first direction. The second linear recess 1t2 is located above the third gap G3 and extends in the longitudinal direction of the third gap G3 when the first protective layer 1 is viewed in plan. In other words, the second linear recess 1t2 is located above the third gap G3 and extends in the negative Y-direction as the first direction when the first protective layer 1 is viewed in plan. The second linear recess 1t2 is a groove located on the first surface 1f and extending in the negative Y-direction as the first direction.

In the example in FIGS. 19 to 21, a single second linear recess 1t2 is located above a first third gap G3 between the first support 5 and the solar cell 3 arranged in the positive X-direction as the second direction. A single second linear recess 1t2 is located above a second third gap G3 between the solar cell 3 and the second support 5 arranged in the positive X-direction as the second direction. Thus, in the example in FIGS. 19 to 21, three second linear recesses 1t2 are arranged in the positive X-direction as the second direction.

For example, the second linear recess 1t2 connects with two or more of the first linear recesses 1t1. In the example in FIGS. 19 to 21, the second linear recess 1t2 connects with each of the five first linear recesses 1t1 arranged in the negative Y-direction as the first direction. More specifically, each of the three second linear recesses 1t2 connects with the five first linear recesses 1t1 arranged in the negative Y-direction as the first direction. The multiple first linear recesses 1t1 and the multiple second linear recesses 1t2 intersecting and connecting with one another form an integral grid-shaped groove. More specifically, the five first linear recesses 1t1 and the three second linear recesses 1t2 intersecting and connecting with one another form an integral grid-shaped groove.

When, for example, the solar cell module 100 is used outdoors for power generation, the solar cell module 100 may be installed with the first surface If facing obliquely upward. More specifically, for example, the solar cell module 100 may be installed with the first end E1 located diagonally downward and the second end E2 located diagonally upward. As described above, for example, the linear recess 1t on the first surface 1f may include the first linear recesses 1t1 and the second linear recesses 1t2 connecting with the first linear recesses 1t1. In this structure, rainwater flowing from above the solar cell elements 31 into the first linear recesses 1t1 on the first surface 1f can easily flow along the first linear recesses 1t1 and the second linear recesses 1t2. Thus, for example, the rainwater flowing along the one or more linear recesses 1t is less likely to reach the first areas A1 on the first surface 1f and can drain from the first surface 1f more easily. This can further reduce, for example, the amount of rainwater to dry on the first areas A1 of the first surface 1f. Dust and mud in rainwater are thus less likely to adhere to the first areas A1 of the first surface 1f. Thus, the solar cell module 100 can have, for example, still higher power generation efficiency.

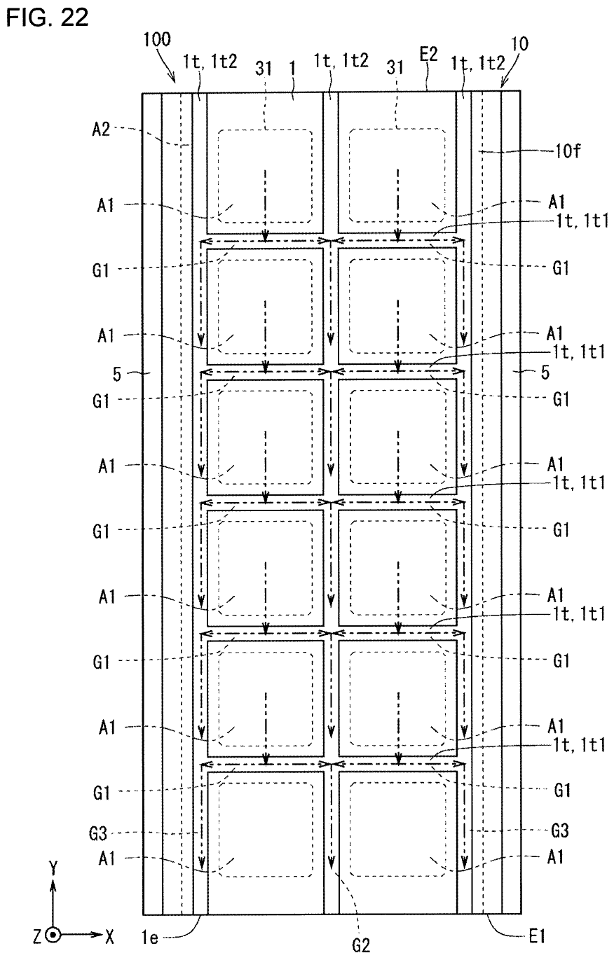

More specifically, for example, as illustrated in FIG. 22, rainwater flowing from above the solar cell elements 31 into the first linear recesses 1t1 flows along the first linear recesses 1t1, and can easily flow into and flow along the second linear recesses 1t2 along paths indicated by the two-dot-dash arrows. In FIG. 22, the example paths of rainwater flowing on the first surface 1f are schematically illustrated by the two-dot-dash arrows. To simplify the drawing, FIG. 22 does not illustrate the solar cell 3, with the outer edges of the solar cell elements 31 indicated by the thin broken lines.

When, for example, the second linear recesses 1t2 extend to an edge 1e of the first surface 1f in the negative Y-direction as the first direction, rainwater flowing along the second linear recesses 1t2 can drain from the first surface 1f still more easily. This can still further reduce, for example, the amount of rainwater to dry on the first areas A1 on the first surface 1f. Dust and mud in rainwater are thus less likely to adhere to the first areas A1 on the first surface 1f. Thus, for example, the solar cell module 100 can have still higher power generation efficiency.

For example, each of the first linear recesses 1t1 and each of the second linear recesses 1t2 may form a round corner or a cut corner when the first surface 1f is viewed in plan. The corner may have a shape fitting to the corresponding one of the four cut corners of the solar cell elements 31. In this case, for example, rainwater can easily flow from the first linear recesses 1t1 into the second linear recesses 1t2.

For example, the second linear recesses 1t2 may not extend to the edge 1e of the first surface 1f in the negative Y-direction as the first direction. In this case as well, for example, rainwater flowing along the second linear recesses 1t2 can easily flow on the first surface 1f except on the first areas A1. This can reduce, for example, the amount of rainwater to dry on the first areas A1 on the first surface 1f.

### 2-2-2. Method for Manufacturing Solar Cell Module

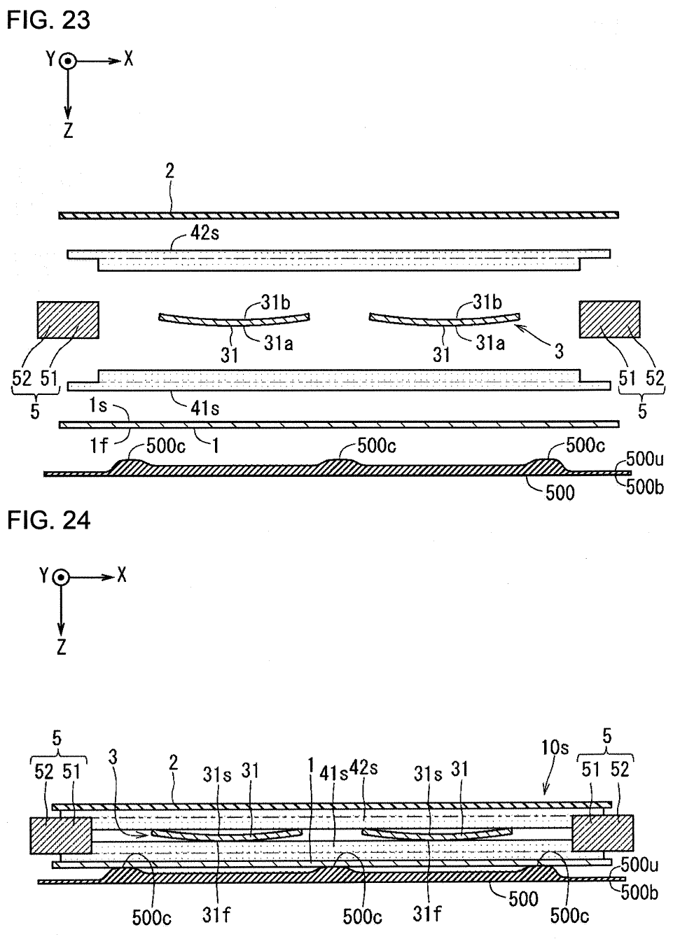

A method for manufacturing the solar cell module 100 according to the third embodiment will now be described with reference to FIGS. 23 and 24.

In this example, based on the method for manufacturing the solar cell module 100 according to the first embodiment, for example, the first protective layer 1, the first sheet 41s, the solar cell 3 and the supports 5, the second sheet 42s, and the second protective layer 2 are stacked on a base 500 in this order to form a stack 10s as illustrated in FIGS. 23 and 24.

The base 500 serves as a mold for forming the one or more linear recesses 1t in an intended pattern on the first surface 1f in laminating the stack 10s. The base 500 includes, for example, a plate member including a flat lower surface 500b and an upper surface 500u with an intended protrusion and recess pattern. The upper surface 500u includes, for example, a protrusion 500c. In the example in FIGS. 23 and 24, the upper surface 500u includes multiple protrusions 500c. Each of the protrusions 500c has a shape corresponding to the shape of the corresponding one of the one or more linear recesses 1t formed through laminating. The material for the base 500 is, for example, glass or metal. The base 500 may be manufactured by various processing methods including, for example, dissolving a glass plate with a chemical solution, or grinding or polishing a glass plate or a metal plate.

To laminate the stack 10s, for example, the base 500 on which the stack 10s is placed is placed on a heater plate in a chamber in a laminator as illustrated in FIG. 24. In this state, the stack 10s is heated while the air pressure in the chamber in the laminator is being reduced. The stack 10s is then pressed in the positive Z-direction with a pressing member such as a diaphragm sheet. This integrates the stack 10s. The first protective layer 1 deforms and the first sheet 41s and the second sheet 42s flow based on the protrusions and recesses on the upper surface 500u of the base 500. This causes the first protective layer 1 to have the first surface 1f including the one or more linear recesses 1t. The solar cell panel 10 according to the third embodiment can thus be obtained. Subsequently, for example, a terminal box is attached to the solar cell panel 10, and portions of the third wires 34 are connected to terminals in the terminal box. The solar cell module 100 according to the third embodiment can thus be manufactured.

### 2-3. Fourth Embodiment

### 2-3-1. Solar Cell Module

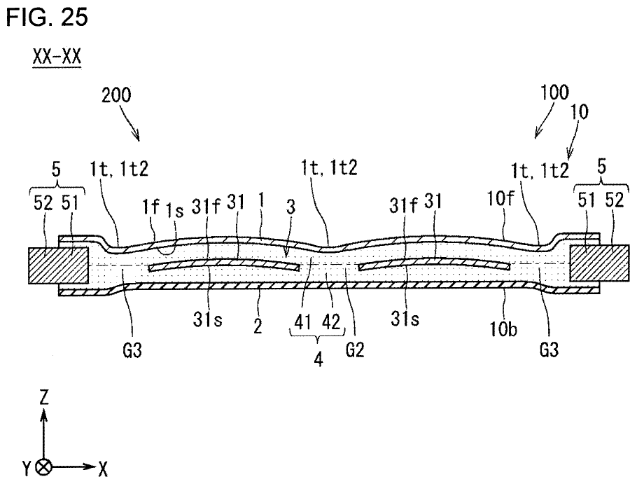

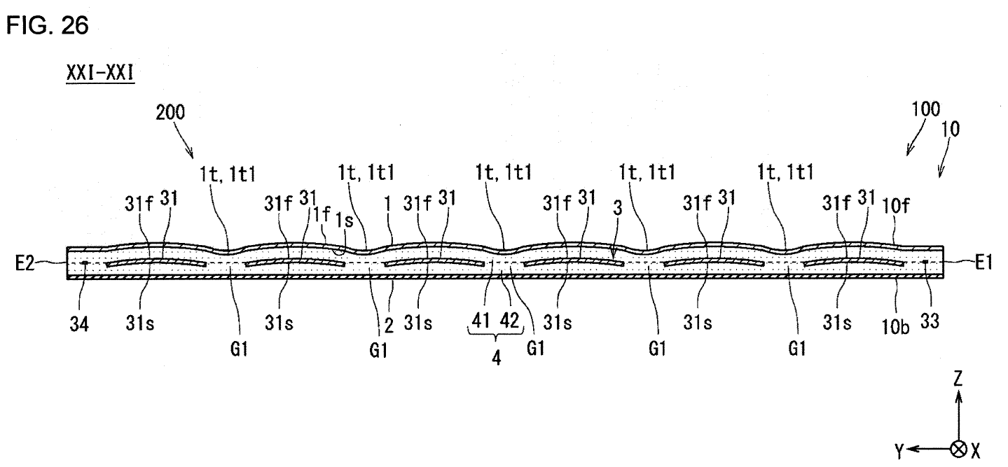

In the above third embodiment, as illustrated in at least one of FIG. 25 or FIG. 26, for example, the first surface 1f may curve convexly following the first element surface 31f of each of the multiple solar cell elements 31. In other words, each of the first areas A1 on the first surface 1f may curve convexly following the corresponding first element surface 31f. Note that each of the first areas A1 on the first surface 1f curving convexly following the corresponding first element surface 31f may have the same curvature as the first element surface 31f, or a curvature slightly different from the first element surface 31f.

When, for example, the solar cell module 100 is used outdoors for power generation, the solar cell module 100 may be installed with the first surface 1f facing obliquely upward. More specifically, for example, the solar cell module 100 may be installed with the first end E1 located diagonally downward and the second end E2 located diagonally upward. In a solar cell module 100 according to a fourth embodiment, for example, each of the first areas A1 on the first surface 1f curves convexly following the corresponding one of the solar cell elements 31. Thus, for example, rainwater can easily flow from each of the first areas A1 toward the one or more linear recesses 1t in the second area A2 on the first surface 1f. This can reduce, for example, the likelihood of rainwater accumulating on the first areas A1 on the first surface 1f, and can reduce the amount of rainwater to dry on the first areas A1 on the first surface 1f. Thus, for example, dust and mud in rainwater are less likely to adhere to the first areas A1 on the first surface 1f. Thus, for example, sunlight entering the solar cell elements 31 is less likely to be blocked by dirt on the first surface 1f. Thus, for example, the solar cell module 100 can have still higher power generation efficiency.

In the fourth embodiment, for example, each of portions of the first surface 1f following the respective first element surfaces 31f may curve along an imaginary arc with a radius of about several hundred to several thousand millimeters.

For example, for each of the portions of the first surface 1f following the respective first element surfaces 31f, one of the YZ cross section or the XZ cross section curves convexly in the direction away from the corresponding first element surface 31f.

For example, as illustrated in FIG. 25, each of the portions of the first surface 1f following the respective first element surfaces 31f has the XZ cross section curving convexly in the direction away from the corresponding first element surface 31f. In this case, each of the portions of the first surface 1f following the respective first element surfaces 31f curves, for example, convexly along the fifth imaginary arc surface described above.

For example, as illustrated in FIG. 26, each of the portions of the first surface 1f following the respective first element surfaces 31f may have the YZ cross section curving convexly in the direction away from the corresponding first element surface 31f. In this case, each of the portions of the first surface 1f following the respective first element surfaces 31f curves, for example, convexly along the sixth imaginary arc surface described above.

For example, for each of the portions of the first surface If following the respective first element surfaces 31f, both the YZ cross section and the XZ cross section may curve convexly in the direction away from the corresponding first element surface 31f. In this case, for example, each of the portions of the first surface 1f following the respective first element surfaces 31f may curve along an imaginary spherical surface. More specifically, for example, each of the portions of the first surface 1f following the respective first element surfaces 31f may curve convexly along a portion of the third imaginary sphere described above.

### 2-3-2. Method for Manufacturing Solar Cell Module

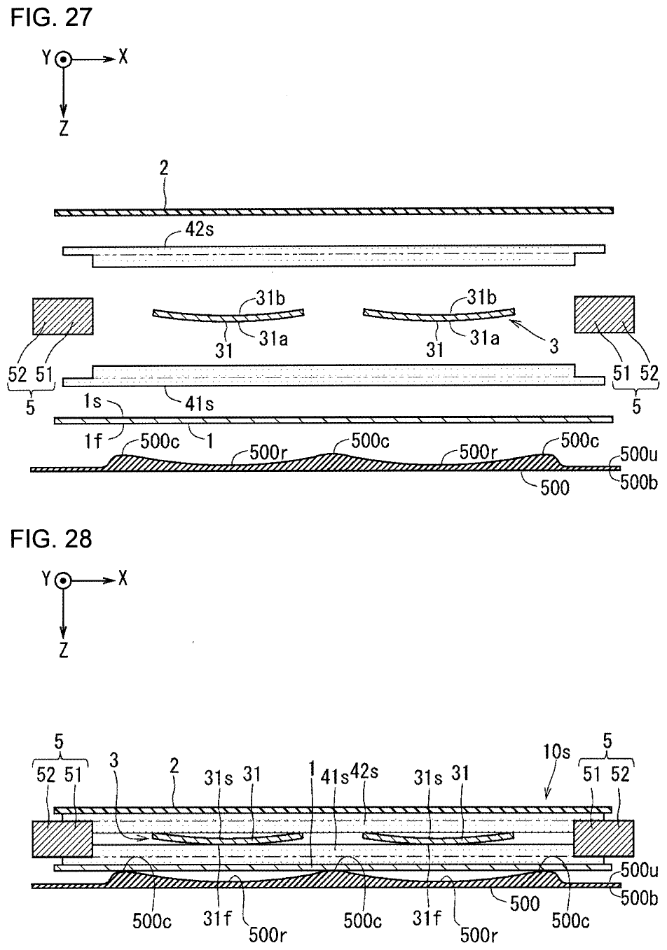

A method for manufacturing the solar cell module 100 according to the fourth embodiment will now be described with reference to FIGS. 27 and 28.

In this example, based on the method for manufacturing the solar cell module 100 according to the third embodiment, for example, the base 500 additionally includes a concave portion 500r on the upper surface 500u as illustrated in FIGS. 27 and 28. In the example in FIGS. 27 and 28, the base 500 additionally includes multiple concave portions 500r on the upper surface 500u. In other words, the base 500 serves as a mold for forming one or more linear recesses 1t in an intended pattern and an intended convex shape on the first surface 1f in laminating the stack 10s.

To laminate the stack 10s, for example, the base 500 on which the stack 10s is placed is placed on a heater plate in a chamber in a laminator as illustrated in FIG. 28. In this state, the stack 10s is heated while the air pressure in the chamber in the laminator is being reduced. The stack 10s is then pressed in the positive Z-direction with a pressing member such as a diaphragm sheet. This integrates the stack 10s. The first protective layer 1 deforms and the first sheet 41s and the second sheet 42s flow based on the protrusions and recesses on the upper surface 500u of the base 500. This causes the first protective layer 1 to have the first surface 1f including the one or more linear recesses 1t and curves convexly following the each of the first element surfaces 31f. The solar cell panel 10 according to the fourth embodiment can thus be obtained. Subsequently, for example, a terminal box is attached to the solar cell panel 10, and portions of the third wires 34 are connected to terminals in the terminal box. The solar cell module 100 according to the fourth embodiment can thus be manufactured.

### 3. Other Embodiments

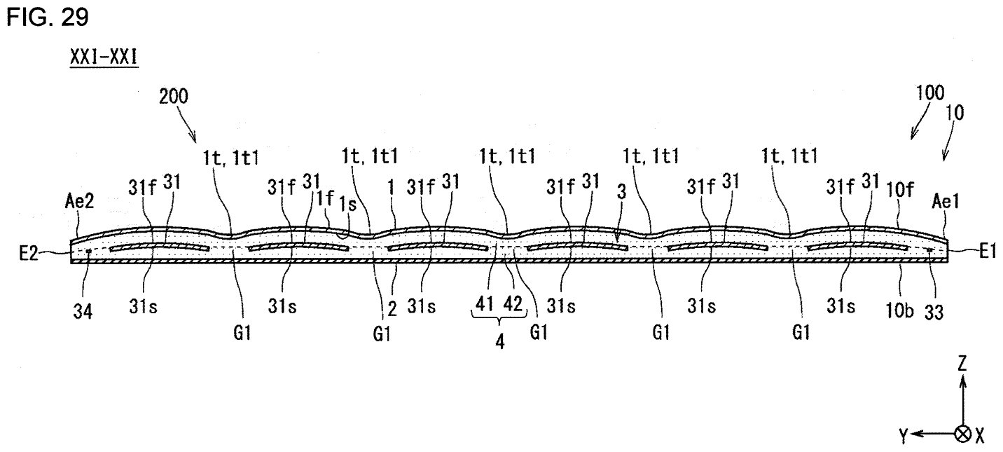

In each of the above embodiments, as illustrated in FIG. 29, for example, a first end area Ae1 of the first surface 1f may curve more in the negative Z-direction as the third direction at a farther position in the negative Y-direction as the first direction. The first end area Ae1 is located at an end of the first surface 1f in the negative Y-direction as the first direction. In other words, the first surface 1f includes the first end area Ae1 at its end in the negative Y-direction as the first direction. The negative Z-direction as the third direction corresponds to a direction from the first surface 1f to the second surface 1s along the thickness direction of the first protective layer 1. In the example in FIG. 29, the first end area Ae1 of the first surface 1f monotonically curves more in the negative Z-direction as the third direction at a farther position in the negative Y-direction as the first direction. This structure may be achieved by, for example, placing a member with a shape corresponding to the shape of the first end area Ae1 between the heater plate in the laminator and the stack 10s as appropriate in integrating the stack 10s by laminating.

When, for example, used outdoors for power generation, the solar cell module 100 is installed with the first surface 1f facing upward or obliquely upward. In this example, with the first end area Ae1 of the first surface 1f curving more in the negative Z-direction as the third direction at a farther position in the negative Y-direction as the first direction, for example, rainwater drains from the first surface 1f easily. Thus, for example, rainwater is less likely to accumulate on the first surface 1f, and dust and mud in rainwater are less likely to adhere to the first surface 1f. Thus, for example, the solar cell module 100 can have higher power generation efficiency.

For example, as illustrated in FIG. 29, a second end area Ae2 of the first surface 1f may curve more in the negative Z-direction as the third direction at a farther position in the positive Y-direction as the fifth direction. The second end area Ae2 is located at an end of the first surface 1f in the positive Y-direction as the fifth direction. In other words, the first surface 1f includes the second end area Ae2 at its end in the positive Y-direction as the fifth direction. In the example in FIG. 29, the second end area Ae2 of the first surface 1f monotonically curves more in the negative Z-direction as the third direction at a farther position in the positive Y-direction as the fifth direction. This structure may be achieved by, for example, placing a member with a shape corresponding to the shape of the second end area Ae2 between the heater plate in the laminator and the stack 10s as appropriate in integrating the stack 10s by laminating.

When, for example, used outdoors for power generation, the solar cell module 100 is installed with the first surface 1f facing upward or obliquely upward. In this example, with the second end area Ae2 of the first surface 1f curving more in the negative Z-direction as the third direction at a farther position in the positive Y-direction as the fifth direction, for example, rainwater drains from the first surface 1f easily. Thus, for example, rainwater is less likely to accumulate on the first surface 1f, and dust and mud in rainwater are less likely to adhere to the first surface 1f. Thus, for example, the solar cell module 100 can have higher power generation efficiency.

In each of the above embodiments, for example, the supports 5 may be replaced by two or more supports 5 arranged in the negative Y-direction as the first direction. In this case, for example, the two or more supports 5 may be arranged at intervals in the negative Y-direction as the first direction.

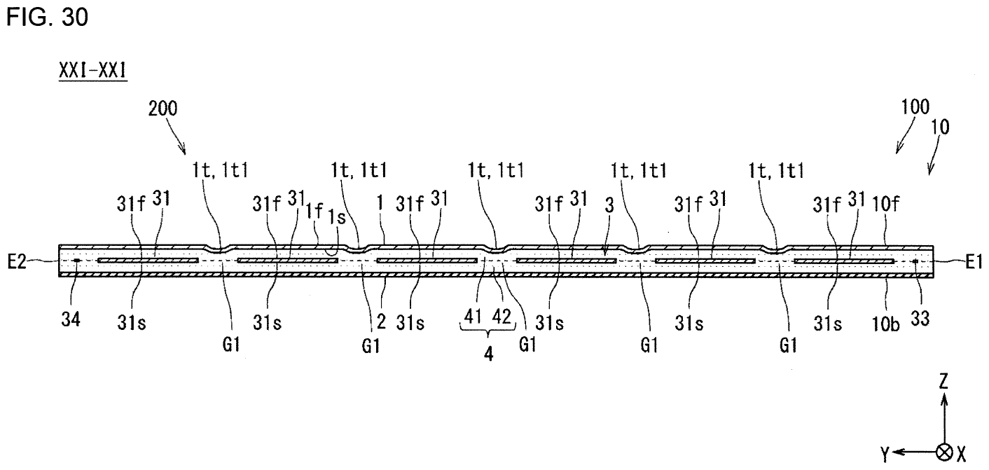

In the above third embodiment, as illustrated in FIG. 30, for example, the first element surface 31f may not curve convexly and the second element surface 31s may not curve concavely in each of the solar cell elements 31. In other words, each of the solar cell elements 31 may be flat. In this case as well, the first protective layer 1 is made of, for example, a light-transmissive resin. Thus, the first protective layer 1 can be thinner, allowing the solar cell module 100 to be lighter. For example, the first surface 1f includes one or more linear recesses It that are located on portions other than above the multiple solar cell elements 31. Thus, for example, rainwater easily flows through the one or more linear recesses 1t on the first surface 1f and is less likely to accumulate on the first areas A1 of the first surface 1f located above the solar cell elements 31. This can reduce, for example, the amount of rainwater to dry on the first areas A1 of the first surface 1f. Thus, for example, dust and mud in rainwater are less likely to adhere to the first areas A1 on the first surface 1f. Thus, for example, sunlight entering the solar cell elements 31 is less likely to be blocked by dirt on the first surface 1f. Thus, the solar cell module 100 can be lighter and have higher power generation efficiency.

In the above third and fourth embodiments, for example, the one or more second linear recesses 1t2 may be located above at least of the second gap G2 or the third gap G3.

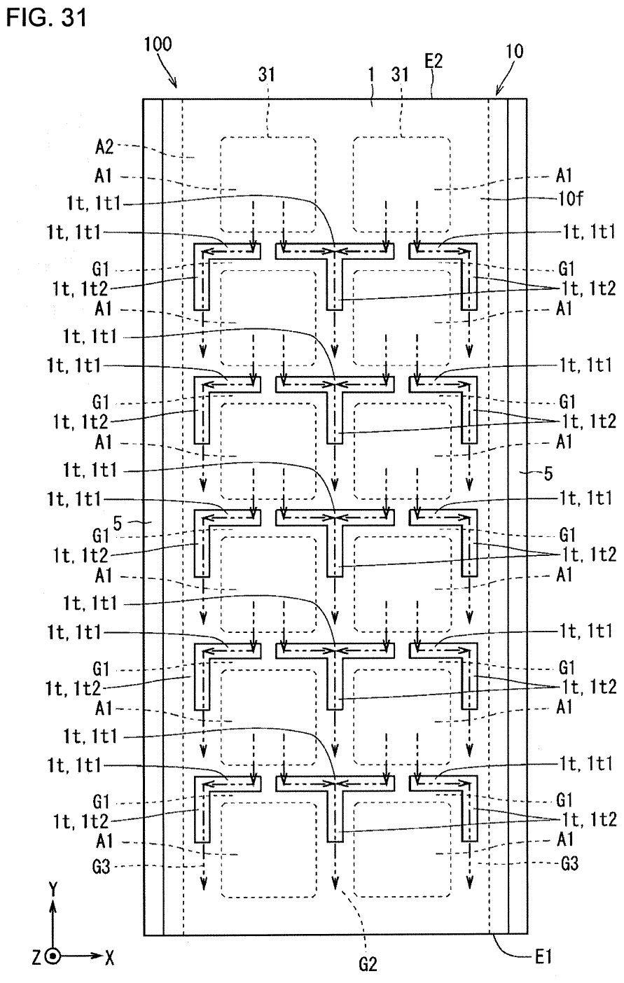

In the above third and fourth embodiments, for example, as illustrated in FIG. 31, the one or more linear recesses 1t may form multiple grooves rather than an integral grid-shaped groove. In other words, the first surface 1f may include multiple linear recesses. For example, the first surface 1f may include one or more first linear recesses 1t1 and may include one or more second linear recesses 1t2. The one or more first linear recesses 1t1 may include, for example, multiple first linear recesses 1t1 arranged in the positive X-direction as the second direction. The one or more second linear recesses 1t2 may include, for example, multiple second linear recesses 1t2 arranged in the negative Y-direction as the first direction.

In the example in FIG. 31, each of the first linear recesses 1t1 illustrated in FIGS. 19 and 22 is replaced by three first linear recesses 1t1 arranged in the positive X-direction as the second direction. In other words, the first surface 1f includes five recess rows each including three first linear recesses 1t1. Each of the second linear recesses 1t2 illustrated in FIGS. 19 and 22 is replaced by five second linear recesses 1t2 arranged in the negative Y-direction as the first direction. In other words, the first surface 1f includes three recess rows each including five second linear recesses 1t2.

In the example in FIG. 31, on a middle portion of the first surface 1f in the positive X-direction as the second direction when the first surface 1f is viewed in plan, each of the first linear recesses 1t1 and the corresponding second linear recesses 1t2 connect with each other to form a T-shaped recess. In this example, each of the second linear recesses 1t2 may not connect with a middle portion of the corresponding first linear recess 1t1 in the X-direction. For example, each of the second linear recesses 1t2 may connect with any portion of the corresponding first linear recess 1t1 in the positive X-direction as the second direction. For example, any portion of each of the first linear recesses 1t1 in the positive X-direction as the second direction may intersect and connect with any portion of the corresponding second linear recess 1t2 in the negative Y-direction as the first direction in a cross shape.

In the example in FIG. 31, on a portion of the first surface 1f in the negative X-direction as the fourth direction when the first surface 1f is viewed in plan, one of the first linear recesses 1t1 and the corresponding second linear recess 1t2 connect with each other to form an L-shaped recess. On a portion of the first surface 1f in the positive X-direction as the second direction when the first surface 1f is viewed in plan, another of the first linear recesses 1t1 and the corresponding second linear recess 1t2 connect with each other to form an L-shaped recess. In this example, each of the first linear recesses 1t1 and the corresponding second linear recess 1t2 may not connect with each other to form the L-shaped recess. For example, each of the first linear recesses 1t1 and any portion of the corresponding second linear recess 1t2 in the negative Y-direction as the first direction may connect with each other to form a T-shaped recess.

When, for example, the solar cell module 100 is used outdoors for power generation, the solar cell module 100 may be installed with the first surface 1f facing obliquely upward. For example, the solar cell module 100 may be installed with the first end E1 located diagonally downward and the second end E2 located diagonally upward. As described above, for example, the one or more linear recesses 1t on the first surface 1f may include the first linear recesses 1t1 and the second linear recesses 1t2 connecting with the respective first linear recesses 1t1. In this structure, rainwater flowing from above the solar cell elements 31 into the first linear recesses 1t1 on the first surface 1f can easily flow along the first linear recesses 1t1 and the second linear recesses 1t2. Thus, for example, the rainwater flowing along the one or more linear recesses 1t is less likely to reach the first areas A1 on the first surface 1f and can drain from the first surface 1f more easily. This can further reduce, for example, the amount of rainwater to dry on the first areas A1 of the first surface 1f. Dust and mud in rainwater are thus less likely to adhere to the first areas A1 of the first surface 1f.

More specifically, for example, as illustrated in FIG. 31, rainwater flowing from above the solar cell elements 31 into the first linear recesses 1t1 flows along the first linear recesses 1t1, and can easily flow into and flow along the second linear recesses 1t2 along paths indicated by the two-dot-dash arrows. In FIG. 31, the example paths of rainwater flowing on the first surface 1f are schematically illustrated by the two-dot-dash arrows. To simplify the drawing, FIG. 31 does not illustrate the solar cell 3, with the outer edges of the solar cell elements 31 indicated by the thin broken lines.

For example, the second linear recesses 1t2 may not extend to the edge 1e of the first surface 1f in the negative Y-direction as the first direction as illustrated in FIG. 31, or may extend to the edge 1e of the first surface 1f in the negative Y-direction as the first direction. For example, the first linear recesses 1t1 and the second linear recesses 1t2 may connect with one another to form one or more linear recesses. In this case as well, for example, rainwater flowing from above the solar cell elements 31 into the first linear recesses 1t1 on the first surface 1f can easily flow along the first linear recesses 1t1 and the second linear recesses 1t2. Thus, for example, the rainwater flowing along the one or more linear recesses 1t is less likely to reach the first areas A1 on the first surface 1f and can drain from the first surface 1f more easily.

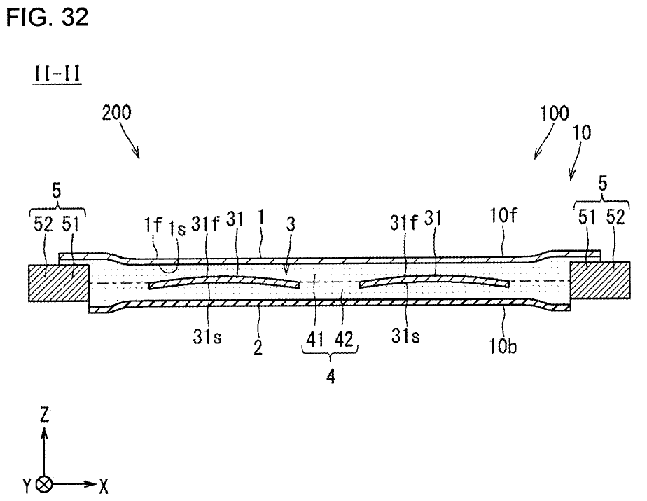

In each of the above embodiments, for example, the first portion 51 of each of the supports 5 may not face the second protective layer 2 as illustrated in FIG. 32. In this case, for example, the second filler 42 does not include the portions each located between the second protective layer 2 and the corresponding first portion 51 in the negative Z-direction as the third direction.

In each of the above embodiments, for example, the solar cell module 100 may further include a reinforced fiber member. The reinforced fiber member is located along, for example, an end of the solar cell panel 10 without the supports 5 and is covered by the filler 4. For example, the reinforced fiber member may be located along at least of the first end E1 or the second end E2 of the solar cell panel 10. The reinforced fiber member is made of, for example, aramid fibers such as Kevlar (registered trademark) fibers or carbon fibers. The reinforced fiber member is elongated along an end of the solar cell panel 10. The reinforced fiber member does not overlap the solar cell 3 when viewed in plan. The reinforced fiber member is easily deformable but has high strength. The reinforced fiber member can thus improve the strength of the solar cell panel 10 without reducing the flexibility of the solar cell panel 10.

In each of the above embodiments, for example, the second wire 33 and the third wires 34 may have a greater width and a greater thickness to improve the strength of the solar cell panel 10 at the first end E1 and the second end E2.

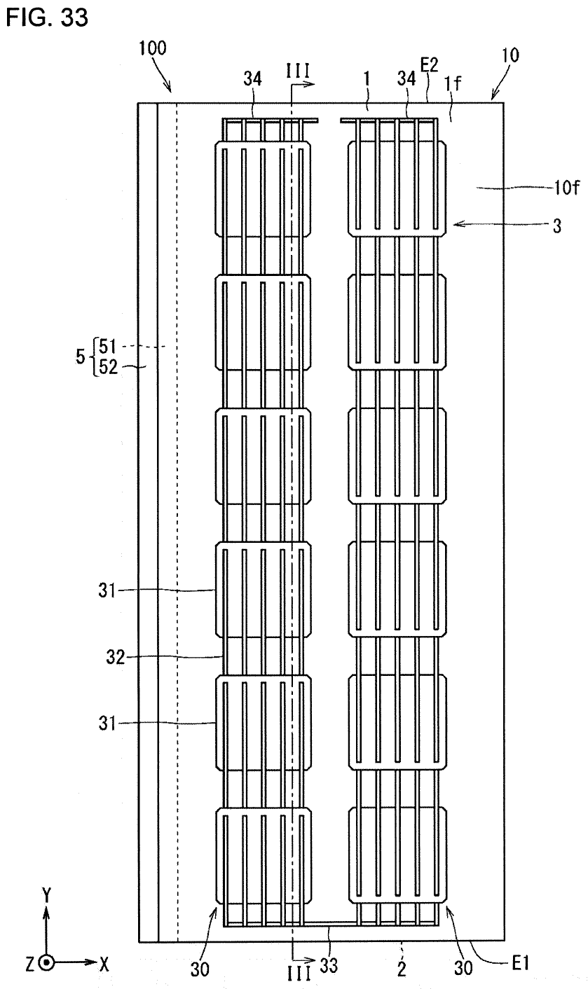

In each of the above embodiments, as illustrated in FIG. 33, for example, the solar cell panel 10 may eliminate one of the first support 5 or the second support 5 included in the two supports 5. In this case as well, the solar cell module 100 including one or more supports 5 can be easily and stably fixed to the attachment destination portion. Additionally, the solar cell panel 10 not including the supports 5 at its three sides can bend in more directions. Thus, the solar cell panel 10 can be more flexible.

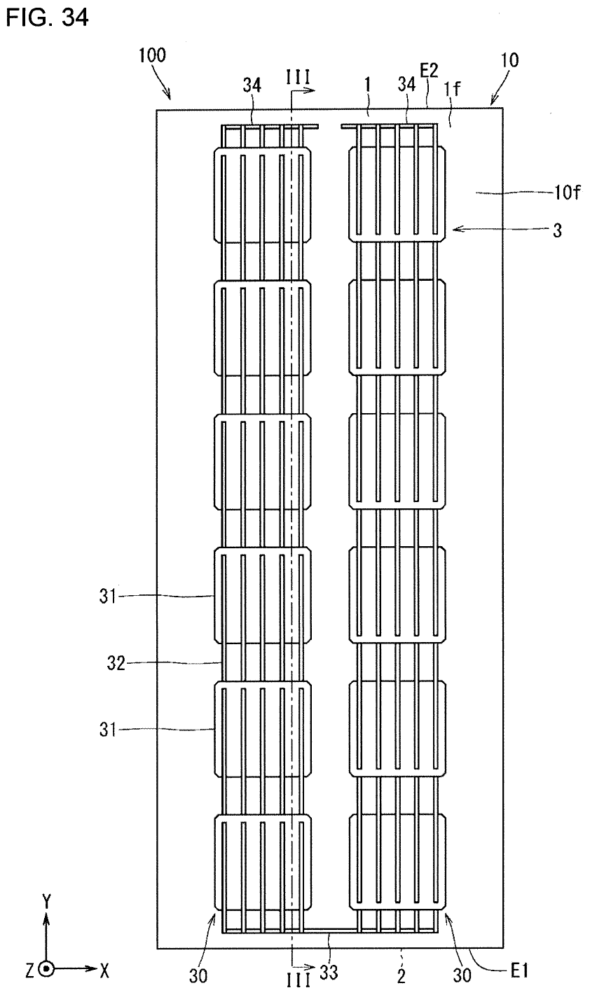

For example, as illustrated in FIG. 34, the solar cell panel 10 may not include the two supports 5.

In each of the above embodiments, for example, some of the multiple solar cell elements 31 may include the first element surface 31f curving convexly and the second element surface 31s curving concavely. In other words, for example, one or more of the multiple solar cell elements 31 include the first element surface 31f curving convexly and the second element surface 31s curving concavely. In this case as well, for example, the one or more solar cell elements 31 curving convexly toward the first protective layer 1 can reduce shock to the solar cell elements 31 when various objects such as falling objects and flying objects hit the first protective layer 1. The solar cell elements 31 are thus less likely to break.

In this example, the first surface 1f may curve convexly following the first element surfaces 31f of the one or more solar cell elements 31. In other words, for example, the first surface 1f may curve convexly following the first element surface 31f of each of the one or more solar cell elements 31. In this case as well, for example, areas on the first surface 1f above the one or more solar cell elements 31 are less likely to be soiled. Thus, for example, sunlight entering the solar cell elements 31 is less likely to be blocked by dirt on the first surface 1f, allowing the solar cell module 100 to have higher power generation efficiency.

In each of the above embodiments, for example, the solar cell 3 may include multiple solar cell elements 31 arranged one-dimensionally. In this example, the solar cell 3 may include, as the multiple solar cell elements 31, two or more solar cell elements 31 arranged in the negative Y-direction as the first direction. In this case as well, the multiple solar cell elements 31 in the solar cell 3 include two solar cell elements 31 arranged in the negative Y-direction as the first direction.

In each of the above embodiments, for example, the second protective layer 2 may be eliminated. In this case, for example, a gaseous free acid such as acetic acid generated in the filler 4 may be eliminated from the filler 4 in the negative Z-direction. Thus, for example, the solar cell 3 may be less likely to have failures caused by the free acid.

In each of the above embodiments, for example, the two supports 5 may be located at two sides of the solar cell panel 10 in the Y-direction, instead of the two sides in the X-direction. In this structure, the solar cell panel 10 can bend in an arc when viewed in the positive X-direction. When the number (arrangement number) of solar cell elements 31 arranged in the Y-direction is an even number, the solar cell panel 10 includes no solar cell elements 31 at its middle in the Y-direction. In other words, the solar cell panel 10 has its middle in the Y-direction located between two solar cell elements 31 adjacent to each other in the Y-direction. Thus, when the solar cell panel 10 bends under a load applied from, for example, accumulated snow and receives a relatively large stress at its middle in the Y-direction, the stress applied to each of the solar cell elements 31 is less likely to increase.

In each of the above embodiments, for example, the first direction and the second direction may intersect with each other without being orthogonal to each other. In other words, the first direction and the second direction may intersect with each other at an angle of 90 degrees or at an angle other than 90 degrees. The angle other than 90 degrees may be, for example, from 60 to less than 90 degrees, from 70 to less than 90 degrees, or from 80 to less than 90 degrees.

In each of the above embodiments, for example, the multiple solar cell elements 31 may be thin film solar cells. Each of the thin-film solar cells may include, for example, a thin film semiconductor and a transparent electrode located on a substrate of, for example, glass or a resin. The thin film semiconductor includes, for example, a silicon-based semiconductor, a compound-based semiconductor, or another semiconductor. The silicon-based thin film semiconductor is, for example, a semiconductor of amorphous silicon or a semiconductor of thin-film polycrystalline silicon. The compound-based thin film semiconductor is, for example, a compound semiconductor with a chalcopyrite structure such as a CIS semiconductor or a CIGS semiconductor, a compound semiconductor of a compound with, for example, a perovskite structure, a compound semiconductor with a kesterite structure, or a cadmium telluride (CdTe) semiconductor. The CIS semiconductor is a compound semiconductor containing copper (Cu), indium (In), and selenium (Se). The CIGS semiconductor is a compound semiconductor containing Cu, In, gallium (Ga), and Se. In this case, for example, the solar cell elements 31 can be curved convexly by using curved substrates.

The solar cell module has been described in detail, but the above structures are illustrative in all respects, and the disclosure is not limited to the above structures. The above embodiments may be combined in any manner unless any contradiction arises. Examples other than those illustrated above may also be included without departing from the scope of the present disclosure.

The present disclosure provides the structures described below.

In one embodiment, (1) a solar cell module includes a first protective layer, a plurality of solar cell elements, and a filler. The first protective layer is made of a light-transmissive resin and includes a first surface and a second surface opposite to the first surface. The plurality of solar cell elements faces the second surface and is arranged along the second surface. The filler is in contact with the second surface and covers the plurality of solar cell elements. The plurality of solar cell elements includes two solar cell elements arranged in a first direction. The first surface includes a first area above the plurality of solar cell elements and a second area different from the first area. The first surface includes one or more linear recesses in the second area.

(2) The solar cell module according to (1) may further include a support adjacent to a solar cell including the plurality of solar cell elements. The support may include a first portion facing the second surface of the first protective layer and a second portion away from the solar cell. The filler may include a portion located between the second surface and the first portion.

(3) In the solar cell module according to (1) or (2), the one or more linear recesses may include a first linear recess and a second linear recess connecting with the first linear recess. The first linear recess may be located above a first gap between the two solar cell elements and extend in a second direction intersecting with the first direction. The second linear recess may extend in the first direction.

(4) In the solar cell module according to (3), the second linear recess may extend to an edge of the first surface in the first direction.

(5) In the solar cell module according to any one of (1) to (4), the first surface may include a first end area at an end of the first surface in the first direction. The first end area may curve more in a third direction at a farther position in the first direction, with the third direction being along a thickness direction of the first protective layer and extending from the first surface to the second surface.

(6) In the solar cell module according to any one of (1) to (5), the plurality of solar cell elements may include one or more solar cell elements. Each of the one or more solar cell elements may include a first element surface facing the second surface and a second element surface opposite to the first element surface. The first element surface may curve convexly, and the second element surface may curve concavely.

(7) In the solar cell module according to (6), the first surface may curve convexly following the first element surface of each of the one or more solar cell elements.

(8) The solar cell module according to any one of (1) to (7) may further include a second protective layer. The second protective layer may be in contact with a surface of the filler opposite to a surface of the filler in contact with the first protective layer. The plurality of solar cell elements may be located between the second surface and the second protective layer.

### REFERENCE SIGNS

1 first protective layer
100 solar cell module
1e edge
1f first surface
1s second surface
1t linear recess
1t1 first linear recess
1t2 second linear recess
2 second protective layer
3 solar cell
31 solar cell element
31f first element surface
31s second element surface
4 filler
5 support
51 first portion
52 second portion
A1 first area
A2 second area
Ae1 first end area
G1 first gap

1. A solar cell module, comprising:
a first protective layer comprising a light-transmissive resin and including a first surface and a second surface opposite to the first surface;
a plurality of solar cell elements facing the second surface and arranged along the second surface; and
a filler in contact with the second surface and covering the plurality of solar cell elements,
wherein the plurality of solar cell elements includes two solar cell elements arranged in a first direction,
the first surface includes a first area above the plurality of solar cell elements and a second area different from the first area, and
the first surface includes one or more linear recesses in the second area.

2. The solar cell module according to claim 1, further comprising:
a support adjacent to a solar cell including the plurality of solar cell elements,
wherein the support includes a first portion facing the second surface of the first protective layer and a second portion away from the solar cell, and
the filler includes a portion located between the second surface and the first portion.

3. The solar cell module according to claim 1, wherein
the one or more linear recesses include a first linear recess and a second linear recess connecting with the first linear recess,
the first linear recess is located above a first gap between the two solar cell elements and extends in a second direction intersecting with the first direction, and
the second linear recess extends in the first direction.

4. The solar cell module according to claim 3, wherein
the second linear recess extends to an edge of the first surface in the first direction.

5. The solar cell module according to claim 1, wherein
the first surface includes a first end area at an end of the first surface in the first direction, and
the first end area curves more in a third direction at a farther position in the first direction, and the third direction is along a thickness direction of the first protective layer and extends from the first surface to the second surface.

6. The solar cell module according to claim 1, wherein
the plurality of solar cell elements includes one or more solar cell elements,
each of the one or more solar cell elements includes a first element surface facing the second surface and a second element surface opposite to the first element surface,
the first element surface curves convexly, and
the second element surface curves concavely.

7. The solar cell module according to claim 6, wherein
the first surface curves convexly following the first element surface of each of the one or more solar cell elements.

8. The solar cell module according to claim 1, further comprising:
a second protective layer,
wherein the second protective layer is in contact with a surface of the filler opposite to a surface of the filler in contact with the first protective layer, and
the plurality of solar cell elements is located between the second surface and the second protective layer.

9. The solar cell module according to claim 2, wherein
the one or more linear recesses include a first linear recess and a second linear recess connecting with the first linear recess,
the first linear recess is located above a first gap between the two solar cell elements and extends in a second direction intersecting with the first direction, and
the second linear recess extends in the first direction.

10. The solar cell module according to claim 9, wherein
the second linear recess extends to an edge of the first surface in the first direction.

11. The solar cell module according to claim 2, wherein
the first surface includes a first end area at an end of the first surface in the first direction, and
the first end area curves more in a third direction at a farther position in the first direction, and the third direction is along a thickness direction of the first protective layer and extends from the first surface to the second surface.

12. The solar cell module according to claim 3, wherein
the first surface includes a first end area at an end of the first surface in the first direction, and
the first end area curves more in a third direction at a farther position in the first direction, and the third direction is along a thickness direction of the first protective layer and extends from the first surface to the second surface.

13. The solar cell module according to claim 9, wherein
the first surface includes a first end area at an end of the first surface in the first direction, and
the first end area curves more in a third direction at a farther position in the first direction, and the third direction is along a thickness direction of the first protective layer and extends from the first surface to the second surface.

14. The solar cell module according to claim 4, wherein
the first surface includes a first end area at an end of the first surface in the first direction, and
the first end area curves more in a third direction at a farther position in the first direction, and the third direction is along a thickness direction of the first protective layer and extends from the first surface to the second surface.

15. The solar cell module according to claim 10, wherein
the first surface includes a first end area at an end of the first surface in the first direction, and
the first end area curves more in a third direction at a farther position in the first direction, and the third direction is along a thickness direction of the first protective layer and extends from the first surface to the second surface.

16. The solar cell module according to claim 2, wherein
the plurality of solar cell elements includes one or more solar cell elements,
each of the one or more solar cell elements includes a first element surface facing the second surface and a second element surface opposite to the first element surface,
the first element surface curves convexly, and
the second element surface curves concavely.

17. The solar cell module according to claim 3, wherein
the plurality of solar cell elements includes one or more solar cell elements,
each of the one or more solar cell elements includes a first element surface facing the second surface and a second element surface opposite to the first element surface,
the first element surface curves convexly, and
the second element surface curves concavely.

18. The solar cell module according to claim 9, wherein
the plurality of solar cell elements includes one or more solar cell elements,
each of the one or more solar cell elements includes a first element surface facing the second surface and a second element surface opposite to the first element surface,
the first element surface curves convexly, and
the second element surface curves concavely.

19. The solar cell module according to claim 4, wherein
the plurality of solar cell elements includes one or more solar cell elements,
each of the one or more solar cell elements includes a first element surface facing the second surface and a second element surface opposite to the first element surface,
the first element surface curves convexly, and
the second element surface curves concavely.

20. The solar cell module according to claim 10, wherein
the plurality of solar cell elements includes one or more solar cell elements,
each of the one or more solar cell elements includes a first element surface facing the second surface and a second element surface opposite to the first element surface,
the first element surface curves convexly, and
the second element surface curves concavely.
